(19) United States
(12) Patent Application Publication
(10) Pub. No.: US 2026/0190396 A1
(43) Pub. Date: Jul. 2, 2026

(54) Thin Film Transistor, Array Substrate and Manufacturing Method Therefor

(71) Applicants: Beijing BOE Technology Development Co., Ltd., Beijing (CN); BOE Technology Group Co., Ltd., Beijing (CN)

(72) Inventors: Hehe HU, Beijing (CN); Ce NING, Beijing (CN); Lizhong WANG, Beijing (CN); Dongfang WANG, Beijing (CN); Rui HUANG, Beijing (CN); Pengfei GU, Beijing (CN); Chaolu WANG, Beijing (CN); Fengjuan LIU, Beijing (CN); Zhengliang LI, Beijing (CN); Jiayu HE, Beijing (CN); Jie HUANG, Beijing (CN); Nianqi YAO, Beijing (CN); Kun ZHAO, Beijing (CN); Feifei LI, Beijing (CN)

(21) Appl. No.: 18/727,699

(22) PCT Filed: Apr. 13, 2023
(86) PCT No.: PCT/CN2023/088156

§ 371 Date: Jul. 10, 2024

(51) Int. Cl. H10D 30/67; H10D 86/01; H10D 86/40; H10D 86/60

(52) U.S. Cl. CPC H10D 30/6757; H10D 30/6732; H10D 86/0231; H10D 86/441; H10D 86/60

(57) ABSTRACT

A thin film transistor includes a first electrode, a second electrode, an active layer, and a gate electrode disposed on a base substrate. The first electrode is located on a side of the active layer close to the base substrate, and a first insulation layer is disposed between the first electrode and the active layer, and is provided with a first via. The active layer is electrically connected to the first electrode through the first via. A second insulation layer is disposed between the gate electrode and the active layer. An orthographic projection of the gate electrode is overlapped, at least partially, with an orthographic projection of the first via, on the base substrate, a surface of a side of the gate electrode close to the base substrate is a first surface, a surface of a side of the gate electrode away from the base substrate is a second surface.

### CROSS-REFERENCE TO RELATED APPLICATION

The present application is a U.S. National Phase Entry of International Application No. PCT/CN2023/088156 having an international filing date of Apr. 13, 2023, the entire content of which is hereby incorporated by reference.

### TECHNICAL FIELD

The present disclosure relates to, but is not limited to, a field of display technologies, in particular to a thin film transistor, an array substrate and a manufacturing method therefor.

### BACKGROUND

In recent years, with development of Augmented Reality (AR)/Virtual Reality (VR) technologies, a demand for ultra-high resolution display technologies is increasing. Due to a demand on ultra-high pixel density (PPI) in the AR/VR display technologies, an aperture ratio in the display region decreases significantly, and a backlight power consumption increases significantly.

### SUMMARY

The following is a summary of subject matters described herein in detail. This summary is not intended to limit the protection scope of claims.

Embodiments of the present disclosure provide a thin film transistor, an array substrate, and a manufacturing method therefor.

In one aspect, a thin film transistor is provided in an embodiment of the present disclosure, which includes a first electrode, a second electrode, an active layer and a gate electrode, which are disposed on a base substrate. The active layer is electrically connected with the first electrode and the second electrode, the gate electrode is located on a side of the active layer away from the base substrate, the first electrode is located on a side of the active layer close to the base substrate, a first insulation layer is disposed between the first electrode and the active layer, the first insulation layer is provided with a first via, the active layer is electrically connected to the first electrode through the first via, and an orthographic projection of the active layer on the base substrate covers an orthographic projection of the first via on the base substrate. A second insulation layer is disposed between the gate electrode and the active layer; an orthographic projection of the gate electrode on the base substrate is overlapped, at least partially, with the orthographic projection of the first via on the base substrate. A surface of a side of the gate electrode close to the base substrate is a first surface, and a surface of a side of the gate electrode away from the base substrate is a second surface, a flatness of the first surface differs from a flatness of the second surface.

In some exemplary implementations, the second surface of the gate electrode is a flat surface, and a vertical distance between the first electrode and the base substrate differs from a vertical distance between the second electrode and the base substrate.

In some exemplary implementations, the active layer includes a channel region, and an orthographic projection of the channel region on the base substrate is located within a range of the orthographic projection of the gate electrode on the base substrate. The channel region includes a first channel portion and a second channel portion connected to each other, an orthographic projection of the first channel portion on the base substrate is overlapped, at least partially, with an orthographic projection of a sidewall of the first via on the base substrate. The second channel portion is located on a surface of a side of the first insulation layer away from the base substrate, and is not overlapped with the orthographic projection of the first via on the base substrate.

In some exemplary implementations, an included angle between the first channel portion and the second channel portion ranges from 90 degrees to 160 degrees in a plane perpendicular to the base substrate and parallel to an extending direction of the active layer.

In some exemplary implementations, a ratio of a length of the second channel portion to a length of the first channel portion is greater than or equal to 1, and a ratio of a thickness of the second channel portion to a thickness of the first channel portion is greater than or equal to 1.

In some exemplary implementations, a length of the first channel portion is greater than 0 and less than or equal to 5 microns, and a length of the second channel portion is greater than 0 and less than or equal to 5 microns.

In some exemplary implementations, the second electrode is located on the side of the active layer close to the base substrate, and the active layer is directly lapped with the second electrode.

In some exemplary implementations, the active layer, the second insulation layer, and the gate electrode are sequentially disposed within the first via.

In some exemplary implementations, a flat layer is disposed between the second insulation layer and the gate electrode, an orthographic projection of the flat layer on the base substrate covers at least the orthographic projection of the first via on the base substrate.

In some exemplary implementations, the orthographic projection of the flat layer on the base substrate covers the orthographic projection of the gate electrode on the base substrate, and the second surface of the gate electrode is a flat surface.

In some exemplary implementations, an orthographic projection of the second insulation layer on the base substrate covers at least orthographic projections of the first via and the gate electrode on the base substrate.

In some exemplary implementations, the second insulation layer includes a plurality of inorganic films stacked, the plurality of inorganic films satisfy at least one of the following: at least one inorganic film has a dielectric constant greater than or equal to 7, and a thickness of each inorganic film is greater than or equal to 50 nanometers.

In another aspect, an array substrate is provided in an embodiment of the present disclosure, which includes: a base substrate, and at least one thin film transistor abovementioned, at least one data line, at least one gate line, and at least one pixel electrode, which are disposed on the base substrate. A gate electrode of the thin film transistor is electrically connected with a gate line, a first electrode of the thin film transistor is electrically connected with a data line, and a second electrode of the thin film transistor is electrically connected with a pixel electrode.

In some exemplary implementations, the first electrode of the thin film transistor and the data line are of an integral structure, the gate electrode of the thin film transistor and the gate line are of an integral structure, and the second electrode of the thin film transistor and the pixel electrode are of an integral structure.

In some exemplary implementations, an orthographic projection of an active layer of the thin film transistor on the base substrate is partially overlapped with an orthographic projection of at least one of the data line and the gate line on the base substrate.

In some exemplary implementations, the base substrate includes a display region where the at least one data line intersects with the at least one gate line to form a plurality of sub-pixel regions, a sub-pixel region includes an opening region for display and a non-opening region on at least one side of the opening region, and the pixel electrode is located at least within the opening region; the thin film transistor, the data line and the gate line are located in the non-opening region.

In some exemplary implementations, a second insulation layer is disposed between the gate electrode and the active layer of the thin film transistor, a flat layer is disposed between the second insulation layer and the gate electrode, and the flat layer is not overlapped with the opening region.

In some exemplary implementations, the array substrate further includes a third insulation layer and a common electrode which are located on a side of the gate line away from the base substrate. The common electrode is located at least within the opening region, and an orthographic projection of the common electrode on the base substrate is, at least partially, overlapped with an orthographic projection of the pixel electrode on the base substrate.

In some exemplary implementations, the array substrate further includes a fourth insulation layer located on a side of the third insulation layer away from the base substrate, the fourth insulation layer is not overlapped with the opening region.

In another aspect, a manufacturing method for an array substrate is provided in an embodiment of the present disclosure. The method includes: forming a first conductive layer on the base substrate, herein the first conductive layer includes a first electrode of at least one thin film transistor; forming a first insulation layer on the first conductive layer, herein the first insulation layer is provided with a first via to expose at least part of a surface of the first electrode; forming a second conductive layer and a semiconductor layer on the first insulation layer, herein the semiconductor layer includes an active layer of the thin film transistor, the active layer is electrically connected to the first electrode through the first via, an orthographic projection of the active layer on the base substrate covers an orthographic projection of the first via on the base substrate, and the second conductive layer at least includes a second electrode of the thin film transistor; forming a second insulation layer; and forming a third conductive layer on the second insulation layer, herein the third conductive layer at least includes a gate electrode of the thin film transistor, a surface of a side of the gate electrode close to the base substrate is a first surface, a surface of a side of the gate electrode away from the base substrate is a second surface, and a flatness of the first surface is different from a flatness of the second surface.

In some exemplary implementations, the first conductive layer further includes at least one data line, a first electrode of the at least one thin film transistor and a data line which is connected with the first electrode of the at least one thin film transistor are of an integral structure; the second conductive layer further includes at least one pixel circuit, a second electrode of the at least one thin film transistor and a pixel circuit which is connected with the second electrode of the at least one thin film transistor are of an integral structure; and the third conductive layer further includes at least one gate line, and a gate electrode of the at least one thin film transistor and a gate line which is connected with the gate electrode of the at least one thin film transistor are of an integral structure.

In some exemplary implementations, the manufacturing method further includes: coating a flat thin film on the base substrate after the second insulation layer is formed, and patterning the flat thin film to form a flat layer; or, coating a flat thin film on the base substrate after the second insulation layer is formed, and etching the flat film by using the third conductive layer as a hard mask after the third conductive layer is formed on the flat film, to form a flat layer. An orthographic projection of the flat layer on the base substrate covers the orthographic projection of the first via on the base substrate.

In some exemplary implementations, forming the second insulation layer includes sequentially depositing a plurality of inorganic films on the base substrate after the semiconductor layer is formed, to form the second insulation layer; or sequentially depositing a plurality of inorganic films on the base substrate after the semiconductor layer is formed, and etching at least one of the plurality of inorganic films by using the third conductive layer as a hard mask after the third conductive layer is formed, to form the second insulation layer. The plurality of inorganic films satisfy at least one of the following: a dielectric constant of at least one inorganic film is greater than or equal to 7, and a thickness of each inorganic film is greater than or equal to 50 nanometers.

In some exemplary implementations, the abovementioned manufacturing method further includes: after forming the third conductive layer, sequentially forming a third insulation layer and a fourth conductive layer, or sequentially forming a third insulation layer, a fourth insulation layer and a fourth conductive layer. The fourth conductive layer at least includes: a common electrode; the third insulation layer is an inorganic insulation layer, and the fourth insulation layer is an organic insulation layer. The base substrate includes a display region, at least one data line disposed in the display region intersects with at least one gate line disposed in the display region to form a plurality of sub-pixel regions, a sub-pixel region includes an opening region for display and a non-opening region located on at least one side of the opening region; the fourth insulation layer is not overlapped with the opening region.

Other aspects of the present disclosure may be comprehended after the drawings and the detailed descriptions are read and understood.

### BRIEF DESCRIPTION OF DRAWINGS

Accompanying drawings are used for providing further understanding of technical solutions of the present disclosure, constitute a part of the specification, and are used for explaining the technical solutions of the present disclosure together with embodiments of the present disclosure, but do not constitute limitations on the technical solutions of the present disclosure. Shapes and sizes of one or more components in the drawings do not reflect actual scales, but are only intended to schematically describe contents of the present disclosure.

FIG. 1 is a schematic diagram of an array substrate according to at least one embodiment of the present disclosure.

FIG. 2 illustrates schematically a cross-sectional view of a part of an array substrate according to at least one embodiment of the present disclosure.

FIG. 3 is a plan view of a part of a display region of an array substrate according to at least one embodiment of the present disclosure.

FIG. 4 illustrates schematically a cross-sectional view of a part taken along a direction Q-Q′ in FIG. 3.

FIG. 5A illustrates schematically a plan view of the array substrate after a first conductive layer is formed in FIG. 3.

FIG. 5B illustrates schematically a plan view of the array substrate after a first insulation layer is formed in FIG. 3.

FIG. 5C illustrates schematically a plan view of the array substrate after a second conductive layer is formed in FIG. 3.

FIG. 5D illustrates schematically a plan view of the array substrate after a semiconductor layer is formed in FIG. 3.

FIG. 6 illustrates schematically another cross-sectional view of a part of an array substrate according to at least one embodiment of the present disclosure.

FIG. 7 is another plan view of a part of a display region of an array substrate according to at least one embodiment of the present disclosure.

FIG. 8 is a cross-sectional view of a part taken along a direction P-P′ in FIG. 7.

FIG. 9A is a plan view of the array substrate after a second conductive layer is formed in FIG. 7.

FIG. 9B illustrates schematically a plan view of the array substrate after a semiconductor layer is formed in FIG. 7.

FIG. 10 illustrates schematically another cross-sectional view of a part of an array substrate according to at least one embodiment of the present disclosure.

FIG. 11A is another plan view of a part of a display region of an array substrate according to at least one embodiment of the present disclosure.

FIG. 11B is a plan view of a flat layer in FIG. 11A and a film on a side of the flat layer close to the base substrate.

FIG. 11C is a plan view of the array substrate after a semiconductor layer is formed in FIG. 11A.

FIG. 12 illustrates schematically another cross-sectional view of a part of an array substrate according to at least one embodiment of the present disclosure.

FIG. 13 illustrates schematically another cross-sectional view of a part of an array substrate according to at least one embodiment of the present disclosure.

FIG. 14 illustrates schematically another cross-sectional view of a part of an array substrate according to at least one embodiment of the present disclosure.

FIG. 15 illustrates schematically another cross-sectional view of a part of an array substrate according to at least one embodiment of the present disclosure.

FIG. 16A is another plan view of a part of a display region of an array substrate according to at least one embodiment of the present disclosure.

FIG. 16B is a plan view of the array substrate after a semiconductor layer is formed in FIG. 16A.

FIG. 16C is a plan view of the array substrate after a second conductive layer is formed in FIG. 16A.

FIG. 17 illustrates schematically another cross-sectional view of a part of an array substrate according to at least one embodiment of the present disclosure.

FIG. 18 illustrates schematically another cross-sectional view of a part of an array substrate according to at least one embodiment of the present disclosure.

FIG. 19 illustrates schematically another cross-sectional view of a part of an array substrate according to at least one embodiment of the present disclosure.

FIG. 20 illustrates schematically another cross-sectional view of a part of an array substrate according to at least one embodiment of the present disclosure.

FIG. 21 is a schematic diagram of a display apparatus according to at least one embodiment of the present disclosure.

### DETAILED DESCRIPTION

The embodiments of the present disclosure will be described below with reference to the drawings in detail. Implementations may be implemented in multiple different forms. Those of ordinary skills in the art may easily understand such a fact that implementations and contents may be transformed into one or more forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one implementation of the present disclosure is not necessarily limited to the dimensions, and shapes and sizes of a plurality of components in the accompanying drawings do not reflect actual scales. In addition, the accompanying drawings schematically illustrate ideal examples, and an implementation of the present disclosure is not limited to shapes, numerical values, or the like shown in the drawings.

Ordinal numerals such as “first”, “second” and “third” in the present disclosure are set to avoid confusion between constituent elements, but not intended for restriction in quantity. “A plurality of” in the present disclosure means two or more in quantity.

In the present disclosure, for convenience, wordings indicating orientation or positional relationship such as “middle”, “upper”, “lower”, “front”, “rear”, “vertical”, “horizontal”, “top”, “bottom”, “inner” and “outer” are employed to explain positional relationship between the constituent elements with reference to the accompanying drawings, they are employed for ease of description and simplification of the description only, but do not indicate or imply that the referred device or element must have a particular orientation, be constructed and operate in a particular orientation, and therefore cannot be construed as limitations on the present disclosure. The positional relationships between the constituent elements are changed as appropriate based on directions according to which the constituent elements are described. Therefore, appropriate replacements based on situations are allowed, which is not limited to the expressions in the specification.

In the present disclosure, the terms “mounted”, “connected” and “connection” are to be understood broadly, unless otherwise expressly specified and defined. For example, a connection may be fixed connection, or a detachable connection, or an integral connection; it may be a mechanical connection or an electrical connection; it may be a direct connection, or an indirect connection through middleware, or internal communication inside two elements. Those of ordinary skills in the art may understand meanings of the aforementioned terms in the present disclosure according to situations.

In the present disclosure, a transistor refers to an element including at least three terminals, i.e., a gate, a drain, and a source. The transistor has a channel region between the drain electrode (drain electrode terminal, drain region, or drain) and the source electrode (source electrode terminal, source region, or source), and a current can flow through the drain electrode, the channel region, and the source electrode. In the present disclosure, the channel region refers to a region through which a current mainly flows.

In the present disclosure, to distinguish two electrodes of a transistor except the gate electrode, one of the electrodes is referred to as a first electrode and the other electrode is referred to as a second electrode. The first electrode may be a source electrode or a drain electrode, and the second electrode may be a drain electrode or a source electrode. In addition, the gate electrode of the transistor is referred to as a control electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the present disclosure.

In the present disclosure, “electric connection” includes a case where constituent elements are connected through an element with a certain electrical effect. The “element with a certain electrical effect” is not particularly limited as long as electrical signals between the connected constituent elements may be transmitted. Examples of the “element with the certain electrical effect” not only include electrodes and wirings, but also include switching elements such as transistors, resistors, inductors, capacitors, other elements with one or more functions, etc.

In the present disclosure, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 800 and below 100°, and thus may include a state in which the angle is above 850 and below 95°.

In the present disclosure, “about” and “substantially” refer to that a boundary is not defined strictly and a case within a range of process and measurement errors is allowed.

In the present disclosure, flatness may refer to surface undulations that can be observed at a macro scale, for example, with a naked eye or an optical microscope. The flatness may also refer to microscopic surface roughness and flatness of a corresponding cross section observed by microscopic morphology characterization means and instruments, such as a Scanning Electron Microscope (SEM) or an Atomic Force Microscope (AFM) at a micro scale. A flat surface means that there is no obvious fluctuation on the surface at a corresponding scale.

In some implementations, compared with an Etched Stopper Layer (ESL) thin film transistor and a Back Channel Etch (BCE) thin film transistor, a dimension of a vertical thin film transistor is significantly reduced, which demonstrates an application prospect of vertical thin film transistors in ultra-high PPI display products. The vertical thin film transistor has high carrier mobility, and can be used in an apparatus with high frequency and low bias voltage.

Embodiments provide a thin film transistor, an array substrate, a manufacturing method therefor, and a display apparatus, which can improve a performance of the vertical thin film transistor, thereby reducing a driving power consumption of the array substrate, increasing an aperture ratio of the array substrate and simplifying a manufacturing process.

A thin film transistor is provided in an embodiment, which includes a first electrode, a second electrode, an active layer and a gate electrode, which are disposed on a base substrate. The active layer is electrically connected with the first electrode and the second electrode, the gate electrode is located on a side of the active layer away from the base substrate, the first electrode is located on a side of the active layer close to the base substrate, a first insulation layer is disposed between the first electrode and the active layer, the first insulation layer is provided with a first via, the active layer is electrically connected to the first electrode through the first via, and an orthographic projection of the active layer on the base substrate covers an orthographic projection of the first via on the base substrate. A second insulation layer is disposed between the gate electrode and the active layer. An orthographic projection of the gate electrode on the base substrate is overlapped, at least partially, with an orthographic projection of the first via on the base substrate. A surface of a side of the gate electrode close to the base substrate is a first surface, and a surface of a side of the gate electrode away from the base substrate is a second surface, a flatness of the first surface differs from a flatness of the second surface.

The thin film transistor provided in the embodiment can ensure a flatness of the film, reduce technological difficulty in a manufacturing process, and improve a performance of the vertical thin film transistor.

In some exemplary implementations, the second surface of the gate electrode can be a flat surface, and a vertical distance between the first electrode and the base substrate differs from a vertical distance between the second electrode and the base substrate. For example, the gate electrode may be filled in the first via, and a flatness of the first surface of the gate electrode may be different from a flatness of the second surface of the gate electrode at a macro scale, and the second surface may be a flat surface.

In some exemplary implementations, the second electrode of the thin film transistor may be located on a side of the active layer close to the base substrate, and the active layer and the second electrode of the thin film transistor may be directly lapped. In this example, the active layer and the second electrode of the thin film transistor are directly lapped, which can reduce an opening process and simplify a manufacturing process. However, the embodiment is not limited thereto. In some other examples, the second electrode and the active layer of the thin film transistor may be of an integral structure.

In some exemplary implementations, a Flat Layer (FL) may be disposed between the second insulation layer and the gate electrode, an orthographic projection of the flat layer on the base substrate may cover at least the orthographic projection of the first via on the base substrate. In some examples, the orthographic projection of the flat layer on the base substrate may cover an orthographic projection of the gate electrode on the base substrate, and the second surface of the gate electrode may be a flat surface. In this example, the flat layer is disposed on a side of the gate electrode close to the base substrate, and the flat layer can be filled in the first via, and the first surface of the gate is in contact with the flat layer. Due to an influence of etching process, the flatness of the first surface is different from the flatness of the second surface of the gate electrode at the micro scale. In this example, by providing the flat layer, a distance between the gate electrode and the first electrode of the thin film transistor can be ensured, so as to improve a voltage rating of the thin film transistor.

In some exemplary implementations, the second insulation layer may include a plurality of inorganic films stacked. The plurality of inorganic films satisfy at least one of the following: a dielectric constant (K value) of at least one inorganic film may be greater than or equal to 7, and a thickness of each inorganic film may be greater than or equal to 50 nanometers. In some examples, a K value of at least one of a plurality of inorganic films is greater than or equal to 7, and a thickness of each inorganic film is greater than or equal to 50 nanometers. For example, a K value of one of the plurality of inorganic films may be greater than or equal to 10. For example, a thickness of at least one inorganic film may be greater than or equal to 50 nanometers, and less than or equal to 300 nanometers. In this example, by setting a plurality of stacked inorganic films as the second insulation layer and limiting the K values and the thicknesses of the inorganic films, characteristics of turning-on and turning-off of the thin film transistor can be ensured while an insulating effect is ensured.

In some examples, the plurality of inorganic films include at least two of the following: an oxide insulation layer, a silicon nitride film, and an HKL film. For example, a K value of the HKL film may be greater than or equal to 10. In some examples, the second insulation layer may include an oxide insulation layer and a silicon nitride film sequentially disposed along a direction away from the base substrate. Or, the second insulation layer may include an oxide insulation layer, an HKL film, and a silicon nitride film sequentially disposed in a direction away from the base substrate. Or, the second insulation layer may include an oxide insulation layer and an HKL film sequentially disposed along a direction away from the base substrate. In this example, a via coverage can be improved by providing the oxide insulation layer. By providing the silicon nitride film, the via coverage can be improved, Electrostatic Discharge (ESD) and short circuit problems caused by a crack of the second insulation layer can be avoided, and the dielectric performance of the second insulation layer can be improved, and resistance to electrical breakdown can be improved. By providing the HKL film, the dielectric performance of the second insulation layer can be improved, a leakage current can be reduced, and the resistance to electrical breakdown can be improved.

An array substrate is also provided in an embodiment, which includes: a base substrate, and at least one thin film transistor abovementioned, at least one data line, at least one gate line, and at least one pixel electrode, which are disposed on the base substrate. A gate electrode of the thin film transistor is electrically connected with a gate line, a first electrode of the thin film transistor is electrically connected with a data line, and a second electrode of the thin film transistor is electrically connected with a pixel electrode. A structure of the thin film transistor in this embodiment can be described as previously.

By ensuring a flatness of the film, with the array substrate provided in this embodiment, process difficulty in the manufacturing process can be reduced, a performance of a vertical thin film transistor can be improved, and further the driving power consumption of the array substrate can be reduced.

In some exemplary implementations, an orthographic projection of an active layer of the thin film transistor on the base substrate may be overlapped, at least partially, with an orthographic projection of the data line on the base substrate. For example, the orthographic projection of the active layer of the thin film transistor on the base substrate may be within a range of the orthographic projection range of the data line on the base substrate. In this example, by forming the thin film transistor at a position of the data line, no extra space may be occupied, thereby improving an aperture ratio of a display region.

In some exemplary implementations, an orthographic projection of an active layer of the thin film transistor on the base substrate may be overlapped, at least partially, with an orthographic projection of the gate line on the base substrate. For example, the orthographic projection of the active layer of the thin film transistor on the base substrate may be within a range of the orthographic projection range of the gate line on the base substrate. In this example, by forming the thin film transistor at a position of the gate line, no extra space may be occupied, thereby improving the aperture ratio of the display region.

In some exemplary implementations, a display apparatus including the array substrate in this embodiment may be a liquid crystal display apparatus. The liquid crystal display apparatus may include the array substrate in this embodiment, an opposed substrate, and a liquid crystal layer disposed between the array substrate and the opposed substrate. In some examples, the display apparatus may be an Advanced Super Dimension Switch (ADS) type display apparatus for a horizontal electric field, or a High-Advanced Dimension Switch (HADS) type display apparatus for a high aperture ratio, or a Vertical Alignment (VA) type display apparatus. The pixel electrode and the common electrode included in the array substrate may be configured to generate an electric field that deflects liquid crystal molecules in the liquid crystal layer. For example, the opposed substrate may include an underlying substrate, a color film, and a black matrix. However, the embodiment is not limited thereto.

Solutions of this embodiment will be described below through multiple examples.

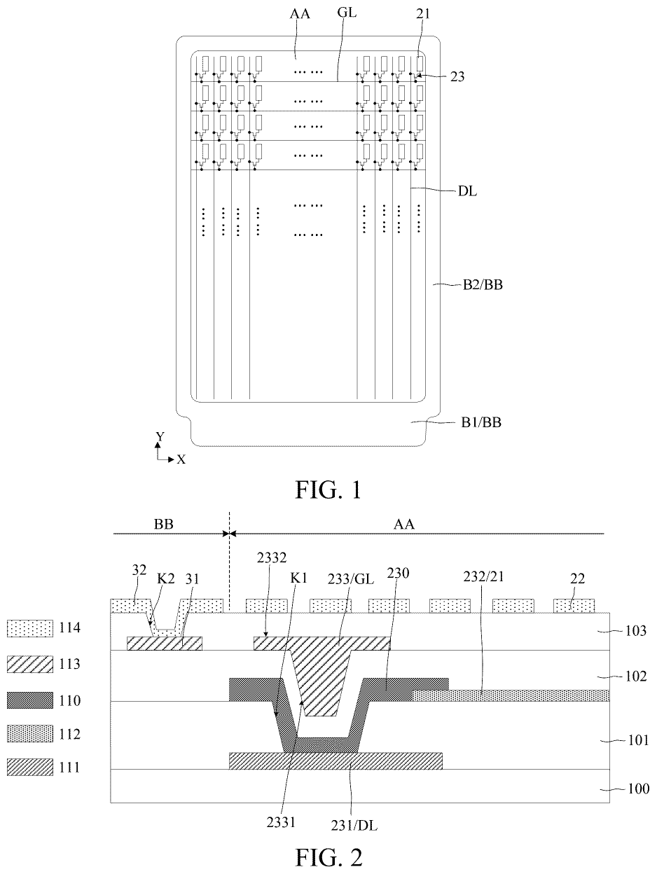

FIG. 1 is a schematic diagram of an array substrate according to at least one embodiment of the present disclosure. In some examples, as shown in FIG. 1, the array substrate may include a display region AA and a bezel region BB surrounding a periphery of the display region AA. The bezel region may include a first bezel region B1 located on a side of the display region AA and a second bezel region B2 located on remaining sides of the display region AA. For example, the first bezel region B1 may include a lower bezel of the array substrate, and the second bezel region B2 may include an upper border, a left border, and a right border of the array substrate.

In some examples, as shown in FIG. 1, the display region AA may include a plurality of data lines DL and a plurality of gate lines GL disposed on a base substrate. The plurality of gate lines GL may extend along a first direction X, and are sequentially arranged along a second direction Y different from the first direction X. The plurality of data lines DL may extend along the second direction Y, and are sequentially arranged along the first direction X. The first direction X may intersect with the second direction Y. For example, the first direction X may be perpendicular to the second direction Y. The plurality of data lines DL and the plurality of gate lines GL may be located in different films. For example, the plurality of data lines DL may be located on a side of the plurality of gate lines GL close to the base substrate.

In some examples, as shown in FIG. 1, the plurality of data lines DL may intersect with the plurality of gate lines GL to form a plurality of sub-pixel regions. A region defined by adjacent data lines DL intersecting with adjacent gate lines GL may be a sub-pixel region. One sub-pixel may be correspondingly disposed in a sub-pixel region. The sub-pixel region may include an opening region and a non-opening region surrounding the opening region. The non-opening region may be a region that is shielded by a black matrix of an opposed substrate of the array substrate, and the opening region may be a region that is not shielded by the black matrix of the opposed substrate. The adjacent gate lines GL and the adjacent data lines DL may be all located in the non-opening region. The array substrate in this embodiment may be configured to implement a display function, and an opening region of each sub-pixel region may be configured for displaying. The non-opening region surrounds the opening region, and does not perform displaying. However, the embodiment is not limited thereto. In some examples, the array substrate may be used for implementing other functions.

In some examples, the display region AA may include a plurality of pixel units disposed on the base substrate. At least one of the pixel units may include three sub-pixels (e.g. a first sub-pixel, a second sub-pixel, and a third sub-pixel arranged in sequence along the first direction X). The three sub-pixels of the pixel unit may be, for example, a blue sub-pixel, a red sub-pixel, and a green sub-pixel, and the three sub-pixels may be arranged sequentially in an order of the blue sub-pixel, the green sub-pixel, and the red sub-pixel. As shown in FIG. 1, at least one sub-pixel may include a pixel electrode 21 and a common electrode (not shown in FIG. 1), the pixel electrode 21 and the common electrode may be located, at least, in the opening region, and an orthographic projection of the pixel electrode 21 of the sub-pixel on the base substrate may be overlapped with an orthographic projection of the common electrode of the sub-pixel on the base substrate. Common electrodes of a plurality of sub-pixels in the display region AA may be of an integral structure. For example, the common electrode may be located on a side of the pixel electrode 21 away from the base substrate. The sub-pixel may further include a thin film transistor 23. The thin film transistor 23 may include a gate electrode, a first electrode, and a second electrode, the gate electrode of the thin film transistor 23 may be electrically connected with a gate line GL, the first electrode of the thin film transistor 23 may be electrically connected with a data line DL, and the second electrode of the thin film transistor 23 may be electrically connected with a pixel electrode 21 of a sub-pixel. The thin film transistor 23 may be configured to provide a data signal transmitted by the data line DL to the pixel electrode 21 of the sub-pixel under control of the gate line GL. In some examples, the thin film transistor 23 may be an oxide thin film transistor, or a low temperature polysilicon thin film transistor. In the following example, it is illustrated by taking that the thin film transistor is an oxide thin film transistor as an example. However, the embodiment is not limited thereto.

FIG. 2 illustrates schematically a cross-sectional view of a part of an array substrate according to at least one embodiment of the present disclosure. In some examples, as shown in FIG. 2, in a direction perpendicular to the array substrate, the array substrate may include a base substrate 100, and a first conductive layer 111, a first insulation layer 101, a second conductive layer 112, a semiconductor layer 110, a second insulation layer 102, a third conductive layer 113, a third insulation layer 103, and a fourth conductive layer 114 that are sequentially disposed on the base substrate 100. Both the first insulation layer 101 and the third insulation layer 103 may also be referred to as Inter Layer Dielectric (ILD) layers, and the second insulation layer 102 may also be referred to as a Gate Insulation (GI) layer. All of the first insulation layer 101, the second insulation layer 102, and the third insulation layer 103 may be inorganic insulation layers.

In some examples, as shown in FIG. 2, the first conductive layer 111 may include a first electrode 231 of a thin film transistor and a data line DL, and the first electrode 231 of the thin film transistor and the data line DL may be of an integral structure. The semiconductor layer 110 may include an active layer 230 of a thin film transistor located in a display region AA. The first insulation layer 101 may be provided with a first via K1, and the active layer 230 of the thin film transistor may be electrically connected to the first electrode 231 of the thin film transistor through the first via K1. An orthographic projection of the active layer 230 of the thin film transistor on the base substrate may cover an orthographic projection of the first via K1 on the base substrate. The second conductive layer 112 may include a second electrode 232 of the thin film transistor and a pixel electrode 21, which are located in the display region AA. The second electrode 232 of the thin film transistor and the pixel circuit 21 may be of an integral structure, and are directly lapped with the active layer 230. The third conductive layer 113 may include a gate electrode 233 of the thin film transistor and a gate line GL which are located in the display region AA, and a first trace 31 located in a bezel region BB. The gate electrode 233 of the thin film transistor and the gate line GL may be of an integral structure. The fourth conductive layer 114 may include a common electrode 22 located in the display region AA, and a second trace 32 located in the bezel region BB. An orthographic projection of the common electrode 22 on the base substrate may be overlapped with an orthographic projection of the pixel electrode 21 on the base substrate. For example, the common electrode 22 may be provided with a plurality of slits which may penetrate the common electrode 22. Extending directions of the plurality of slits may be consistent, for example, extending along a second direction Y. However, the embodiment is not limited thereto. The common electrode may be provided with slits in two different directions to form a two-domain structure, or may be provided with slits in a plurality of different directions to form a multi-domain structure. In some other examples, the common electrode may be a sheet electrode structure without a slit.

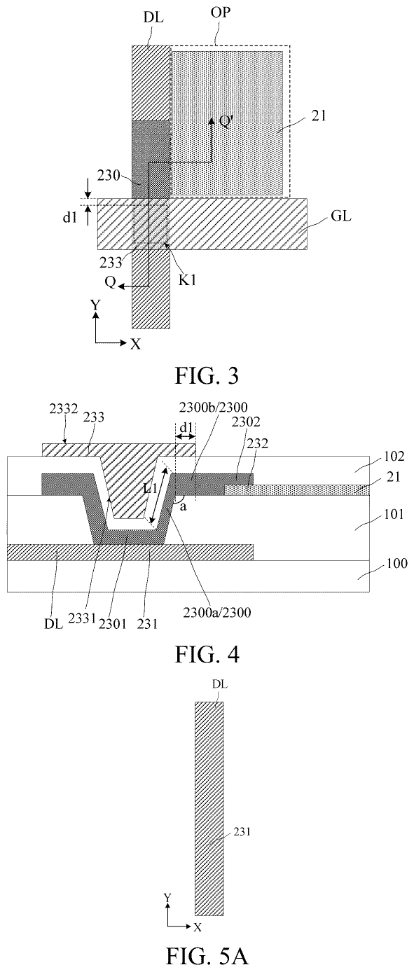

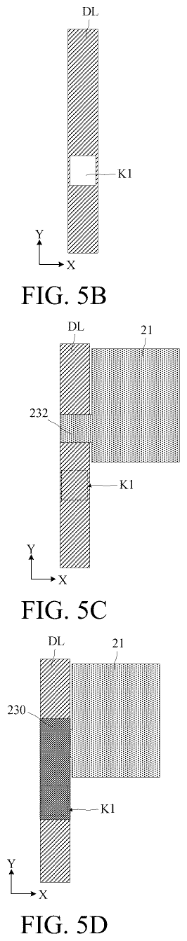

FIG. 3 is a plan view of a part of a display region of an array substrate according to at least one embodiment of the present disclosure. FIG. 4 illustrates schematically a cross-sectional view of a part taken along a direction Q-Q′ in FIG. 3. FIG. 5A illustrates schematically a plan view of the array substrate after a first conductive layer is formed in FIG. 3. FIG. 5B illustrates schematically a plan view of the array substrate after a first insulation layer is formed in FIG. 3. FIG. 5C illustrates schematically a plan view of the array substrate after a second conductive layer is formed in FIG. 3. FIG. 5D illustrates schematically a plan view of the array substrate after a semiconductor layer is formed in FIG. 3.

A manufacturing process for the array substrate in this example will be described below by way of example, with reference to FIGS. 2 to 5D. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film which is made of a material on an underlying substrate by using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process.

In this specification, “A and B are disposed in a same layer” means that A and B are formed simultaneously through a same patterning process using a same material. A “thickness” of a film is a dimension of the film in a direction perpendicular to the display substrate. “An orthographic projection of B is within a range of an orthographic projection of A” or “An orthographic projection of A contains an orthographic projection of B” means that the boundary of the orthographic projection of B falls within a range of the boundary of the orthographic projection of A, or the boundary of the orthographic projection of A is overlapped with the boundary of the orthographic projection of B.

The manufacturing process for the array substrate in this example may include the following acts.

(1-1) A base substrate is provided. In some examples, the base substrate may be a transparent substrate. For example, the base substrate may be a rigid substrate or a flexible substrate. For example, a material of the rigid substrate may include, but is not limited to, one or more of glass and quartz, and a material of the flexible substrate may include, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers. However, the embodiment is not limited thereto.

(1-2) A first conductive layer is formed. In some examples, a first conductive thin film is deposited on the base substrate, and the first conductive thin film is patterned through a patterning process to form a first conductive layer disposed on the base substrate.

In some examples, as shown in FIG. 5A, the first conductive layer in the display region may include a data line DL, and a first electrode 231 of the thin film transistor. The data line DL may be of a strip structure extending along a second direction Y. The data line DL and the first electrode 231 of the thin film transistor may be in an integral structure, for example, a part of the data line DL may serve as the first electrode of the thin film transistor.

In some examples, the first conductive layer may be made of a metal material (e.g. any one or more of titanium (Ti), molybdenum (Mo), aluminum (Al), copper (Cu)), or an alloy material of the abovementioned metals (such as molybdenum alloy (MTD), aluminum neodymium alloy (AlNd), molybdenum titanium alloy (MoTi), or molybdenum niobium alloy (MoNb)), and may be in a monolayer structure, or in a multi-layer composite structure, such as Ti/Al/Ti, Mo/Al/Mo, Mo/Cu/Mo, MTD/Cu/MTD, MoTi/Cu/MoTi, etc. Or, the first conductive layer may be made of a transparent conductive material, e.g. Indium Tin Oxide (ITO), Indium Zinc Oxide (IZO) or the like.

(1-3) A first insulation layer is formed. In some examples, a first insulation thin film is deposited on the base substrate on which the aforementioned structure is formed, and the first insulation thin film is patterned through a patterning process to form a first insulation layer.

In some examples, as shown in FIG. 5B, the first insulation layer may be provided with a first via K1 in the display region. A first insulation layer in the first via K1 can be removed to expose a part of a surface of a Data Line DL in the first conductive layer. An orthographic projection of the first via K1 on the base substrate may be within a range of an orthographic projection of the data line DL on the base substrate. The first via K1 may be configured to enable lapping of the first electrode 231 of the thin film transistor located in the first conductive layer with the active layer 230 located in the semiconductor layer. For example, a sidewall of the first via K1 may be a smooth surface, and a surface of the first electrode of the thin film transistor, which is exposed at a bottom of the first via K1, may be a smooth surface, thereby ensuring a good effect of lapping between the first electrode 231 and the active layer 230 of the thin film transistor. For example, a slope angle of the sidewall of the first via K1 may be less than 80 degrees. The slope angle of the sidewall of the first via K1 refers to an included angle between a plane where the sidewall is located and a horizontal plane where the base substrate 100 is located.

In some examples, a thickness of the first insulation layer may be greater than 0.5 microns. The first insulation layer may be made of any one or more of silicon oxide (SiOₓ, x >0), alumina (Al₂O₃), and hafnium dioxide (HfO₂), and may be mono-layered, multi-layered, or a composite layer. However, the embodiment is not limited thereto.

Providing of the first insulation layer in this example can control a length of a channel region of the active layer, which is beneficial to improving a starting current of the thin film transistor and reducing an area of the thin film transistor, so as to improve an aperture ratio of the display region.

(1-4) A second conductive layer is formed. In some examples, a second conductive thin film is deposited on the base substrate on which the aforementioned structures are formed, and the second conductive thin film is patterned through a patterning process to form a second conductive layer.

In some examples, as shown in FIG. 5C, the second conductive layer in the display region may include a pixel electrode 21 and a second electrode 232 of the thin film transistor. The second electrode 232 of the thin film transistor and the pixel electrode 21 may be in an integral structure. An orthographic projection of the second electrode 232 of the thin film transistor on the base substrate may be overlapped with the orthographic projection of the data line DL on the base substrate, and the pixel electrode 21 may be located, at least, within an opening region OP of the display region. Orthographic projections of the pixel electrode 21 and the second electrode 232 of the thin film transistor on the base substrate are not overlapped with the orthographic projection of the first via K1 on the base substrate. A vertical distance between the second electrode 232 of the thin film transistor and the base substrate 100 differs from a vertical distance between the first electrode 231 of the thin film transistor and the base substrate 100. For example, the vertical distance between the second electrode 232 of the thin film transistor and the base substrate 100 may be greater than the vertical distance between the first electrode 231 of the thin film transistor and the base substrate 100.

In some examples, the second conductive layer may be made of a transparent conductive material such as Indium Tin Oxide (ITO), Indium Zinc Oxide (IZO) and the like.

(1-5) A semiconductor layer is formed. In some examples, a semiconductor thin film is deposited on the base substrate on which the aforementioned structures are formed, and the semiconductor thin film is patterned through a patterning process to form a semiconductor layer.

In some examples, as shown in FIG. 5D, the semiconductor layer in the display region may include an active layer 230 of the thin film transistor 21. An orthographic projection of the active layer 230 on the base substrate may be at least partially overlapped with the orthographic projection of the data line DL on the base substrate. For example, the orthographic projection of the active layer 230 on the base substrate may be within the range of the orthographic projection of the data line DL on the base substrate. The active layer 230 may cover at least a portion of the second electrode 232 of the thin film transistor, for example, covering an overlapping portion of the second electrode 232 of the thin film transistor with the data line DL, thereby enabling direct lapping with the second electrode 232 of the thin film transistor. The active layer 230 may extend along the second direction Y. An orthographic projection of the active layer 230 on the base substrate may cover the orthographic projection of the first via K1 on the base substrate, and the active layer 230 may be electrically connected to the first electrode 231 of the thin film transistor through the first via K1. In this example, by disposing the second electrode 232 of the thin film transistor to be directly lapped with the active layer 230, the opening process can be reduced, and manufacturing acts can be simplified. By providing the active layer 230 on the data line DL, a space of the opening region occupied by the thin film transistor can be reduced, which is beneficial to improving the aperture ratio of the display region.

In some examples, the semiconductor thin film may be a transparent semiconductor thin film. A material of the semiconductor layer may include an oxide semiconductor material. For example, the semiconductor layer may be made of one or more materials of amorphous Indium Gallium Zinc Oxide material (a-IGZO), Zinc Oxide Nitride (ZnON), Indium Zinc Tin Oxide (IZTO) and the like. That is, an embodiment of the present disclosure is suitable for transistors fabricated based on Oxide technologies.

In this example, the active layer and the second electrode of the thin film transistor are lapped by disposing the second electrode of the thin film transistor on the data line. However, the embodiment is not limited thereto. In some other examples, the integral structure of the second electrode of the thin film transistor and the pixel electrode may be located in the opening region, and the active layer in the semiconductor layer is configured to be extended to the opening region to achieve an electrical connection of the active layer with the integral structure of the second electrode of the thin film transistor and the pixel electrode.

(1-6) A second insulation layer and a third conductive layer are formed. In some examples, a second insulation thin film and a third conductive thin film are sequentially deposited on the base substrate on which the aforementioned structures are formed, and the third conductive thin film is patterned through a patterning process to form a second insulation layer and a third conductive layer disposed on the second insulation layer, as shown in FIG. 3.

In some examples, the second insulation layer may be made of any one or more of silicon oxide (SiOₓ, x >0), alumina (Al₂O₃), and hafnium dioxide (HfO₂), and may be mono-layered, multi-layered, or a composite layer. However, the embodiment is not limited thereto.

In some examples, as shown in FIGS. 2 to 4, the third conductive layer may include, at least, a gate electrode 233 of the thin film transistor and a gate line GL, which are located in the display region, and a first trace 31 located in a peripheral region. The gate line GL may be of a strip structure extending along a first direction X. The gate electrode 233 of the thin film transistor and the gate line GL in the display region may be connected to each other to form an integral structure. For example, a part of the gate line GL may serve as the gate electrode 233 of the thin film transistor. An orthographic projection of the integral structure of the gate line GL and the gate electrode 233 of the thin film transistor on the base substrate may cover the orthographic projection of the first via K1 on the base substrate.

In some examples, after the third conductive layer is formed, conducting treatment can be performed on a semiconductor layer not covered by the third conductive layer. For example, a conducting method may include plasma treatment, doping treatment, or the like, by using a gas such as hydrogen (H), ammonia (NH₃), helium (He), argon (Ar), or the like. This embodiment is not limited thereto.

In some examples, a channel region 2300, a first region 2301, and a second region 2302 may be defined through the active layer 230 of the thin film transistor by a conducting process. Conductivities of the first region 2301 and the second region 2302 may be higher than a conductivity of the channel region 2300. The channel region 2300 may be connected between the first region 2301 and the second region 2302, and the first region 2301 of the active layer 230 may be electrically connected with the integral structure of the pixel electrode 21 and the second electrode 232 of the thin film transistor. For example, the integral structure of the pixel electrode 21 and the second electrode 232 of the thin film transistor may contact the second region 2302 of the active layer 230, but not contact the channel region. The first region 2301 of the active layer 230 may be electrically connected with the integral structure of the first electrode 231 of the thin film transistor and the data line DL.

In some examples, as shown in FIGS. 3 and 4, the channel region 2300 of the active layer 230 may include a first channel portion 2300a and a second channel portion 2300b connected to each other. The first channel portion 2300a may be disposed around the sidewall of the first via K1, and the second channel portion 2300b may surround an outer side of the first channel portion 2300a and be located on a horizontal surface of a side of the first insulation layer 101 away from the base substrate 100. The first channel portion 2300a is connected with the first region 2301 of the active layer 230, and the second channel portion 2300b is connected with the second region 2302.

In some examples, as shown in FIGS. 3 and 4, a first included angle may be provided between the first channel portion 2300a and the second channel portion 2300b in a plane, which is perpendicular to a plane where the base substrate is located and is parallel to an extending direction of the active layer 230, and the first included angle a may range from 90 degrees to 160 degrees. For example, the first included angle a may be about 120 degrees, about 100 degrees, or about 135 degrees.

In some examples, a length of the first channel portion 2300a in the extending direction of the channel region 2300 may be a first length L1. For example, the first length L1 may be substantially equal to a length of the sidewall of the first via K1, and the first length of the first channel portion 2300a may refer to an effective length of the first channel portion 2300a. The first length L1 may be greater than 0, and less than or equal to 5 microns. For example, the first length L1 may be about 0.5 microns, or may be about 1 micron.

In some examples, a length of the second channel portion 2300b in the extending direction of the channel region 2300 may be a second length d1. For example, the second length d1 may be a distance between an edge of the first via K1 and an edge of the gate line GL in the extending direction of the active layer 230. The second length d1 may be greater than 0, and less than or equal to 5 microns. For example, the second length d1 may be greater than 0, and less than or equal to 2 microns. For example, the second length d1 may be about 1 microns, or may be about 2 micron.

In some examples, a ratio (i.e. a ratio of d1 to L1) of a length of the second channel portion 2300b to a length of the first channel portion 2300a may be greater than or equal to 1. For example, the length of the second channel portion 2300b may be the same as the length of the first channel portion 2300a, or the length of the second channel portion 2300b may be greater than the length of the first channel portion 2300a.

In some examples, a thickness of the first channel portion 2300a may be a vertical distance between a surface of the first channel portion 2300a away from the sidewall of the first via and a surface of the first channel portion 2300a close to the sidewall of the first via. A thickness of the second channel portion 2300b may be a vertical distance between a surface of the second channel portion 2300b away from the first insulation layer 101 and a surface of the second channel portion 2300b close to the first insulation layer 101. In some examples, the thickness of the first channel portion 2300a may be greater than or equal to 1 nanometer (nm), and less than or equal to 200 nm, and the thickness of the second channel portion 2300b may be greater than or equal to 1 nm, and less than or equal to 200 nm. In some examples, a ratio of a thickness of the second channel portion 2300b to a thickness of the first channel portion 2300a may be greater than or equal to 1. For example, the thickness of the second channel portion 2300b may be substantially the same as the thickness of the first channel portion 2300a, or the thickness of the second channel portion 2300b may be greater than the thickness of the first channel portion 2300a.

In some examples, by controlling the included angle between the first channel portion and the second channel portion, the lengths of the first channel portion and the second channel portion, and the thicknesses of the first channel portion and the second channel portion, a switching characteristic of the thin film transistor can be ensured, and a space occupied by the thin film transistor can be reduced under the premise of ensuring the characteristics of the transistor, so as to achieve an ultra-high resolution display technology.

In some examples, a switching characteristic of the channel region of the thin film transistor may be controlled by controlling the second length d1. For example, when the second length d1 is large, the switching characteristic of the thin film transistor is easy to be ensured, but a starting current Ion is reduced. When the second length d1 is small, the thin film transistor is prone to a conducting problem, but a large starting current can be obtained. In some examples, a size of the second length may be adjusted according to a characteristic control capability and a graphical process capability. For example, the second length d1 may be greater than 0 and less than or equal to 2 microns to ensure the switching characteristic of the channel region of the thin film transistor.

In some examples, as shown in FIG. 4, a surface of a side of the gate electrode 233 of the thin film transistor close to the base substrate 100 is a first surface 2331, and a surface of a side of the gate electrode 233 of the thin film transistor away from the base substrate 100 is a second surface 2332. The second surface 2332 of the gate electrode 233 may be a flat surface. The active layer 230, the second insulation layer 102 and the gate electrode 233 may be sequentially disposed within the first via K1. In this example, a portion of the gate electrode 233 is filled within the first via K1, and a flatness of the first surface 2331 of the gate electrode 233 is different from a flatness of the second surface 2332 at a macro scale. In this example, planarization of the first via K1 is achieved by using the gate electrode 233, a film for planarization of the first via K1 is unnecessary to be disposed at a side of the third conductive layer away from the base substrate. Moreover, the opening region is not provided with a via, and a flat film is also unnecessary to be disposed, thus simplifying the process acts and saving the cost.

In some examples, the third conductive layer may be made of a metal material (e.g. any one or more of titanium (Ti), molybdenum (Mo), aluminum (Al), copper (Cu)), or an alloy material of the abovementioned metals (such as molybdenum alloy (MTD), aluminum neodymium alloy (AlNd), molybdenum titanium alloy (MoTi), or molybdenum niobium alloy (MoNb)), and it may be in a monolayer structure, or in a multi-layer composite structure, such as Ti/Al/Ti, Mo/Al/Mo, Mo/Cu/Mo, MTD/Cu/MTD, MoTi/Cu/MoTi, etc. Or, the first conductive layer may be made of a transparent conductive material, e.g. Indium Tin Oxide (ITO), Indium Zinc Oxide (IZO) or the like.

(1-7) A third insulation layer is formed. In some examples, a third insulation thin film is deposited on the base substrate on which the aforementioned structures are formed, and the third insulation thin film is patterned through a patterning process to form a third insulation layer.

In some examples, as shown in FIG. 2, the third insulation layer may be provided with a plurality of vias in the bezel region BB, for example, a second via K2 may be included. A third insulation layer 103 within the second via K2 may be removed to expose a part of a surface of the first trace 31 located in the third conductive layer. A third insulation layer in the display region does not need to be provided with a via, which is beneficial to improving the aperture ratio of the display region.

In some examples, the third insulation layer may be any one or more of silicon oxide (SiOx, x >0), silicon nitride (SiNy, y >0), alumina (Al₂O₃), and hafnium dioxide (HfO₂), and may be mono-layered, multi-layered, or a composite layer. However, the embodiment is not limited thereto.

(1-8) A fourth conductive layer is formed. In some examples, a fourth conductive thin film is deposited on the base substrate on which the aforementioned structures are formed, and the fourth conductive thin film is patterned through a patterning process to form a fourth conductive layer.

In some examples, as shown in FIG. 2, the fourth conductive layer may include a common electrode 22 located at least in the display region AA, and a second trace 32 located in the bezel region BB. The second trace 32 may be electrically connected to the first trace 31 through a second via K2 opened in the third insulation layer 103. For example, the first trace 31 and at least one gate line may be of an integral structure, and the first trace 31 and the second trace 32 can be electrically connected to achieve transmission of a scanning signal from the bezel region to the display region, thus achieving the transmission and transfer of the scanning signal. As another example, the data line located in the first conductive layer can be electrically connected with a data connection line located in the fourth conductive layer by providing vias in a third insulation layer, a second insulation layer and a first insulation layer in the bezel region, thereby achieving input and transfer of a data signal. In this example, the signal input and transfer are achieved by providing the vias in the bezel region, and the opening region in the display region does not need to be provided with a via, which is beneficial to improving the aperture ratio of the display region.

In some examples, the fourth conductive layer may be made of a transparent conductive material such as Indium Tin Oxide (ITO), Indium Zinc Oxide (IZO) and the like.

In this example, as shown in FIGS. 2 and 4, the active layer 230 of the thin film transistor, the second insulation layer 102, and the top gate electrode 233 of the thin film transistor are sequentially disposed in the first via K1, so that the second surface 2332 on the side of the top gate electrode 233 away from the base substrate 100 can be a flat surface without providing a flat layer on the side of the third conductive layer away from the base substrate, which can reduce the manufacturing process and reduce the cost.

In the manufacturing process for the array substrate in this example, the first conductive layer, the first insulation layer, the second conductive layer, the semiconductor layer, the third conductive layer, the third insulation layer and the fourth conductive layer are respectively formed through seven patterning processes, which can reduce a quantity of masks required in the manufacturing process, and is beneficial to reducing the cost. Moreover, for the display region of the array substrate, only a first via needs to be formed in the first insulation layer to achieve an electrical connection between the active layer of the thin film transistor and the data line, which is beneficial to improving the aperture ratio of the array substrate and achieving an array substrate with high resolution.

The structure of the display substrate and the manufacturing process for the display substrate in an embodiment of the present disclosure are described only as an example. In some examples, a corresponding structure may be changed and a patterning process may be added or reduced according to actual needs. For example, the first insulation thin film and the second conductive thin film can be sequentially deposited on the base substrate, and then the second conductive thin film is patterned to form the second conductive layer, and then the first insulation thin film is patterned to form the first insulation layer. However, the embodiment is not limited thereto.

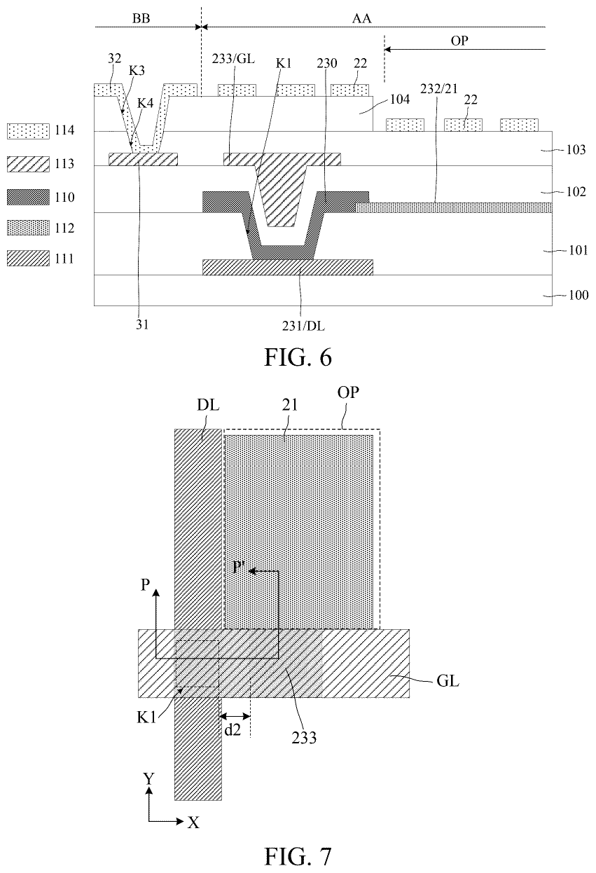

FIG. 6 illustrates schematically another cross-sectional view of a part of an array substrate according to at least one embodiment of the present disclosure. In some examples, as shown in FIG. 6, in a direction perpendicular to the array substrate, the array substrate may include a base substrate 100, and a first conductive layer 111, a first insulation layer 101, a second conductive layer 112, a semiconductor layer 110, a second insulation layer 102, a third conductive layer 113, a third insulation layer 103, a fourth insulation layer 104, and a fourth conductive layer 114 that are sequentially disposed on the base substrate 100. The first insulation layer 101, the second insulation layer 102 and the third insulation layer 103 may be inorganic insulation layers, and the fourth insulation layer 104 may be an organic insulation layer.

In some examples, as shown in FIG. 6, the first conductive layer 111 may include a first electrode 231 of a thin film transistor and a data line DL located in a non-opening region of a display region AA, and the data line DL and the first electrode 231 of the thin film transistor connected thereto may be in an integral structure. The semiconductor layer 110 may include an active layer 230 of a thin film transistor, which is located in the non-opening region of the display region AA. The first insulation layer 101 may be provided with a first via K1 in the non-opening region of the display region AA, and the active layer 230 may be electrically connected to the first electrode 231 of the thin film transistor through the first via K1. An orthographic projection of the active layer 230 on the base substrate 100 may cover an orthographic projection of the first via K1 on the base substrate 100. The second conductive layer 112 may include a second electrode 232 of the thin film transistor and a pixel electrode 21. For example, the second electrode 232 of the thin film transistor may be located in the non-opening region of the display region AA, and the pixel electrode 21 may be located at least in an opening region OP of the display region AA. The second electrode 232 of the thin film transistor and the pixel electrode 21 may be in an integral structure, and are directly lapped with the active layer 230 in the non-opening region. The third conductive layer 113 may include, at least, a gate electrode 233 of the thin film transistor and a gate line GL located in the non-opening region of the display region AA, and a first trace 31 located in a bezel region BB. The gate electrode 233 of the thin film transistor and the gate line GL may be in an integral structure. The fourth conductive layer 114 may include a common electrode 22 located in the display region AA, and a second trace 32 located in the bezel region BB. An orthographic projection of the fourth insulation layer 104 on the base substrate 100 may be not overlapped with an orthographic projection of the opening region OP of the display region AA. In other words, a fourth insulation layer 104 within the opening region OP of the display region AA may be removed. A fourth insulation layer 104 in the bezel region BB may be provided with a third via K3, and a fourth insulation layer 104 within the third via K3 may be removed to expose a surface of the third insulation layer 103. The third insulation layer 103 may be provided with a fourth via K4 in the bezel region BB, and a third insulation layer 103 within the fourth via K4 may be removed to expose a part of a surface of the first trace 31. An orthographic projection of the third via K3 on the base substrate may cover an orthographic projection of the fourth via K4 on the base substrate. The second trace 32 may be electrically connected to the first trace 31 through the fourth via K4 and the third via K3.

In some examples, the fourth insulation layer 104 may be made of an organic material such as polyimide, acrylic, or polyethylene terephthalate. However, the embodiment is not limited thereto.

In some examples, as shown in FIG. 6, in a manufacturing process for the array substrate in this example, after forming the third conductive layer 113, a third insulation thin film may be deposited on the base substrate 100 on which the aforementioned structures are formed, and a fourth insulation thin film may be coated (e.g. spin-coated), the fourth insulation thin film may be patterned through a patterning process to form a fourth insulation layer 104. The fourth insulation layer 104 may be provided with a third via K3 for exposing the surface of the third insulation thin film in the bezel region BB, and a fourth insulation layer 104 in the opening region OP of the display region AA may be removed. Subsequently, the third insulation thin film is patterned through a patterning process to form a third insulation layer 103 which is provided with a fourth via K4 that exposes a part of a surface of the third conductive layer 113 in the bezel region BB. The third via K3 and the fourth via K4 are broken through, so that the second trace 32 located in the fourth conductive layer is electrically connected to the first trace 31 through the third via K3 and the fourth via K4.

According to the array substrate in this example, by providing the fourth insulation layer 104 in the non-opening region of the display region, crosstalk caused by a signal transmitted in the gate line GL to the common electrode 22 can be reduced, and parasitic capacitance between the gate line GL and the common electrode 22 can be reduced. By removing the fourth insulation layer in the opening region OP of the display region AA, a liquid crystal deflection electric field can be ensured, and a liquid crystal electric field effect can be improved. Moreover, for the display region AA, the first via K1 needs to be formed in the first insulation layer 101 to achieve an electrical connection between the active layer of the thin film transistor and the data line, which is beneficial to improving the aperture ratio of the array substrate and achieving the array substrate with high resolution.

Remaining structures of and manufacturing acts for the array substrate in this example may be referred to the description of the aforementioned embodiments, which is not repeated here.

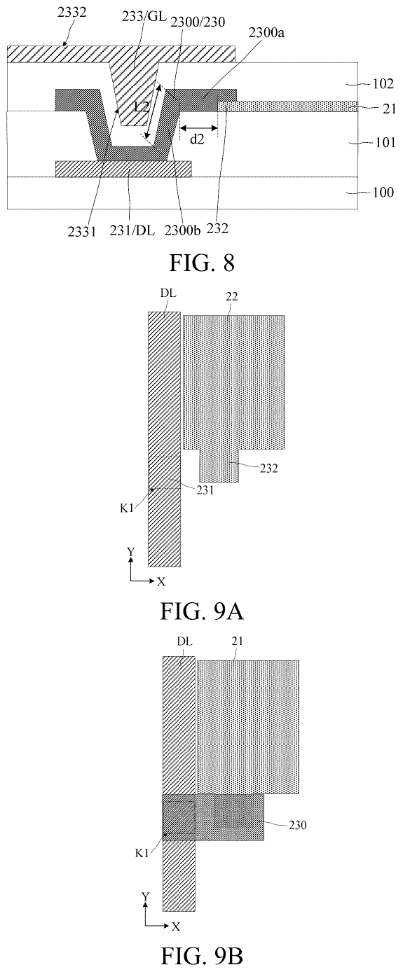

FIG. 7 is another plan view of a part of a display region of an array substrate according to at least one embodiment of the present disclosure. FIG. 8 is a cross-sectional view of a part taken along a direction P-P′ in FIG. 7. FIG. 9A is a plan view of the array substrate after a second conductive layer is formed in FIG. 7. FIG. 9B illustrates schematically a plan view of the array substrate after a semiconductor layer is formed in FIG. 7.

A manufacturing process for the array substrate in this example will be described below by way of example, with reference to FIGS. 7 to 9B. The manufacturing process for the array substrate in this example may include the following acts.

(2-1) A base substrate is provided.

(2-2) A first conductive layer is formed. In some examples, a first conductive thin film is deposited on the base substrate, and the first conductive thin film is patterned through a patterning process to form a first conductive layer provided on the base substrate.

In some examples, as shown in FIG. 9A, the first conductive layer may include a data line DL, and a first electrode 231 of a thin film transistor. The data line DL and the first electrode 231 of the thin film transistor may be in an integral structure.

(2-3) A first insulation layer is formed. In some examples, a first insulation thin film is deposited on the base substrate on which the aforementioned structure is formed, and the first insulation thin film is patterned through a patterning process to form a first insulation layer. As shown in FIG. 9A, the first insulation layer is provided with a first via K1 in a display region, and an orthographic projection of the first via K1 on the base substrate may be within a range of an orthographic projection of the data line DL on the base substrate.

(2-4) A second conductive layer is formed. In some examples, a second conductive thin film is deposited on the base substrate on which the aforementioned structures are formed, and the second conductive thin film is patterned through a patterning process to form a second conductive layer. As shown in FIG. 9A, a second conductive layer in the display region may include a pixel electrode 21 and a second electrode 232 of the thin film transistor. The second electrode 232 of the thin film transistor and the pixel electrode 21 may be in an integral structure. An orthographic projection of the integral structure of the second electrode 232 of the thin film transistor and the pixel electrode 21 on the base substrate may be not overlapped with the orthographic projection of the data line DL on the base substrate.

In some other examples, the first insulation thin film and the second conductive thin film can be sequentially deposited on the base substrate, and then the second conductive thin film is patterned to form the second conductive layer, and then the first insulation thin film is patterned to form the first insulation layer. This embodiment is not limited thereto.

(2-5) A semiconductor layer is formed. In some examples, a semiconductor thin film is deposited on the base substrate on which the aforementioned structures are formed, and the semiconductor thin film is patterned through a patterning process to form a semiconductor layer. In some examples, as shown in FIG. 9B, the semiconductor layer in the display region may include an active layer 230 of the thin film transistor. An orthographic projection of the active layer 230 on the base substrate may be overlapped with an orthographic projection of the second electrode 232 of the thin film transistor on the base substrate, so that the active layer 230 is directly lapped with the second electrode 232 of the thin film transistor. The active layer 230 may extend along a first direction X, and the orthographic projection of the active layer 230 on the base substrate may cover the orthographic projection of the first via K1 on the base substrate, so that the active layer 230 is electrically connected to the first electrode 231 of the thin film transistor through the first via K1. In this example, by arranging the second electrode 232 of the thin film transistor to be directly lapped with the active layer 230, the opening process can be reduced, and manufacturing acts can be simplified. In some other examples, the second electrode of the thin film transistor and the pixel electrode may be disposed within the opening region, and the active layer may extend into the opening region, and is directly lapped with the second electrode of the thin film transistor within the opening region.

(2-6) A second insulation layer and a third conductive layer are formed. In some examples, a second insulation thin film and a third conductive thin film are sequentially deposited on the base substrate on which the aforementioned structures are formed, and the third conductive thin film is patterned through a patterning process to form a second insulation layer and a third conductive layer disposed on the second insulation layer. In some examples, as shown in FIG. 7, the third conductive layer may include, at least, a gate electrode 233 of the thin film transistor and a gate line GL located in the display region. The gate line GL may be of a strip structure extending along the first direction X, and the gate line GL and a gate electrode 233 of the thin film transistor to which the gate line GL is connected may be in an integral structure. An orthographic projection of the integral structure of the gate line GL and the gate electrode 233 of the thin film transistor on the base substrate may cover the orthographic projection of the first via K1 on the base substrate, and is overlapped, at least partially, with the orthographic projection of the second electrode 232 of the thin film transistor on the base substrate, for example, covers the orthographic projection of the second electrode 232 on the base substrate. An orthographic projection of the gate line GL on the base substrate may be overlapped, at least partially, with the orthographic projection of the active layer 230 on the base substrate. For example, the orthographic projection of the gate line GL on the base substrate may cover the orthographic projection of the active layer 230 on the base substrate. In this example, by providing the active layer on the data line, a space of the opening region occupied by the thin film transistor can be reduced, which is beneficial to improving the aperture ratio of the display region.

In some examples, the entire active layer 230 of the thin film transistor is located below the gate line GL, so that conducting processing may not need to be performed on the semiconductor layer, switching of the transistor may be implemented through a scanning signal transmitted by the gate line GL, which may simplify the manufacturing process. A connection position of the active layer 230 of the thin film transistor with the second electrode 232 may be located below the gate line GL, so that crosstalk caused by a signal transmitted by the data line DL to the pixel electrode can be avoided. Since the scanning signal transmitted by the gate line GL has a low frequency variation, crosstalk influence on the pixel electrode can be reduced.

In some other examples, when the active layer is partially overlapped with the gate line, conducting treatment may be performed on the semiconductor layer which is not covered by the gate line by using a conducting process. This embodiment is not limited thereto.

In some examples, as shown in FIGS. 3 and 4, the channel region 2300 of the active layer 230 of the thin film transistor may include a first channel portion 2300a and a second channel portion 2300b which are connected to each other. For example, the first channel portion 2300a may be disposed around the sidewall of the first via K1, and the second channel portion 2300b may surround an outer side of the first channel portion 2300a and be located on a horizontal surface of a side of the first insulation layer 101 away from the base substrate 100.

In some examples, a length of the first channel portion 2300a in the extending direction of the channel region 2300 may be a third length L2. For example, the third length L2 may be substantially equal to a length of the sidewall of the first via K1, and the third length of the first channel portion 2300a may refer to an effective length of the first channel portion 2300a. A length of the second channel portion 2300b in the extending direction of the channel region 2300 may be a fourth length d2. The fourth length d2 of the second channel portion may be a distance between an edge of the first via K1 and an edge of the second electrode of the thin film transistor. In some examples, the third length L2 may be greater than 0, and less than or equal to 5 microns. For example, the third length L2 may be about 0.5 microns, or may be about 1 micron. The fourth length d2 may be greater than 0, and less than or equal to 5 microns. For example, the fourth length d2 may be greater than 0, and less than or equal to 2 microns. For example, the fourth length d2 may be about 1 micron, or may be about 2 microns.

In some examples, a ratio of a length of the second channel portion 2300b to a length of the first channel portion 2300a (i.e. a ratio of d2 to L2) may be greater than or equal to 1. For example, the length of the second channel portion 2300b may be the same as the length of the first channel portion 2300a, or the length of the second channel portion 2300b may be greater than the length of the first channel portion 2300a.

In some examples, a thickness of the first channel portion 2300a may be a vertical distance between a surface of the first channel portion 2300a away from the sidewall of the first via and a surface of the first channel portion 2300a close to the sidewall of the first via. A thickness of the second channel portion 2300b may be a vertical distance between a surface of the second channel portion 2300b away from the first insulation layer 101 and a surface of the second channel portion 2300b close to the first insulation layer 101. In some examples, the thickness of the first channel portion 2300a may be greater than or equal to 1 nanometer (nm), and less than or equal to 200 nm, and the thickness of the second channel portion 2300b may be greater than or equal to 1 nm, and less than or equal to 200 nm. In some examples, a ratio of a thickness of the second channel portion 2300b to a thickness of the first channel portion 2300a may be greater than or equal to 1. For example, the thickness of the second channel portion 2300b may be substantially the same as the thickness of the first channel portion 2300a, or the thickness of the second channel portion 2300b may be greater than the thickness of the first channel portion 2300a.

In some examples, by controlling the included angle between the first channel portion and the second channel portion, the lengths of the first channel portion and the second channel portion, and the thicknesses of the first channel portion and the second channel portion, a switching characteristic of the thin film transistor can be ensured, and a space occupied by the thin film transistor can be reduced under the premise of ensuring the characteristics of the transistor, so as to achieve an ultra-high resolution display technology.

In some examples, a switching characteristic of the channel region of the thin film transistor may be controlled by controlling the fourth length d2. For example, when the fourth length d2 is large, the switching characteristic of the thin film transistor is easy to be ensured, but a starting current Ion is reduced. When the fourth length d2 is small, the thin film transistor is prone to a conducting problem, but a large starting current can be obtained. In some examples, a size of the second length may be adjusted according to a characteristic control capability and a graphical process capability. For example, the fourth length d1 may be greater than 0 and less than or equal to 2 microns to ensure the switching characteristic of the channel region of the thin film transistor. In this example, a short-channel effect can be avoided by controlling a size of the fourth length.

In some examples, as shown in FIGS. 7 and 8, a surface of a side of the gate electrode 233 of the thin film transistor close to the base substrate 100 is a first surface 2331, and a surface of a side of the gate electrode 233 of the thin film transistor away from the base substrate 100 is a second surface 2332. The second surface 2332 of the gate electrode 233 may be a flat surface. The active layer 230, the second insulation layer 102 and the gate electrode 233 may be sequentially disposed within the first via K1. In this example, a portion of the gate electrode 233 is filled within the first via K1, and a flatness of the first surface 2331 of the gate electrode 233 is different from a flatness of the second surface 2332 at a macro scale. In this example, planarization of the first via K1 is achieved by using the gate electrode 233, a film for planarization of the first via K1 may not need to be provided on a side of the third conductive layer away from the base substrate. Moreover, the opening region is not provided with a via, and a flat film is also not needed, thus simplifying the process acts and saving the cost.

(2-7) A third insulation layer and a fourth conductive layer are formed sequentially, or a third insulation layer, a fourth insulation layer and a fourth conductive layer are formed sequentially. For example, the fourth conductive layer may include, at least, a common electrode located in the display region. A fourth insulation layer of the opening region of the display region may be removed. By providing the fourth insulation layer in the non-opening region of the display region, crosstalk caused by a signal transmitted in the gate line to the common electrode can be reduced, and parasitic capacitance between the gate line and the common electrode can be reduced. By removing the fourth insulation layer in the opening region of the display region, a liquid crystal deflection electric field can be ensured, and a liquid crystal electric field effect can be improved.

The manufacturing process for the array substrate in this example can reduce the quantity of masks required, which is beneficial to reducing the cost. Moreover, for the display region of the array substrate, only a first via in the first insulation layer needs to be formed to achieve an electrical connection between the active layer of the thin film transistor and the data line, and the opening region of the display region is not provided with a via, which can be beneficial to improving the aperture ratio of the array substrate and achieving an array substrate with high resolution. Moreover, the active layer of the thin film transistor is located below the gate line, which can avoid crosstalk caused by a data signal to pixel electrodes, reduce an extra space occupied by the thin film transistor, minimize a space occupied by the thin film transistor, and achieve an ultra-high resolution (for example, greater than 2000 PPI) display technology.

Remaining structures of and manufacturing processes for the array substrate in this example may be referred to the description of the aforementioned embodiments, which is not repeated here.

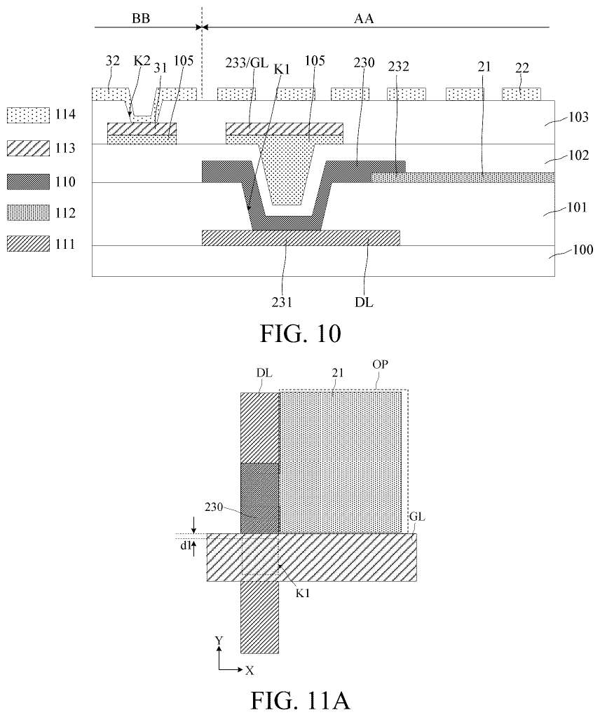

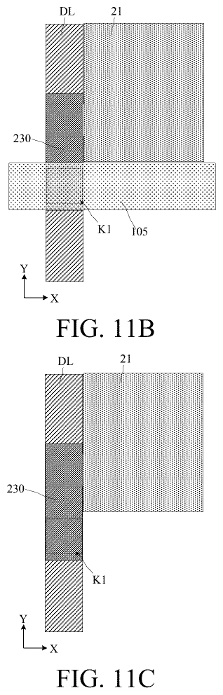

FIG. 10 illustrates schematically another cross-sectional view of a part of an array substrate according to at least one embodiment of the present disclosure. FIG. 11A is another plan view of a part of a display region of an array substrate according to at least one embodiment of the present disclosure. FIG. 11B is a plan view of a flat layer in FIG. 11A and a film on a side of the flat layer close to the base substrate. FIG. 11C is a plan view of the array substrate after a semiconductor layer is formed in FIG. 11A.

In some examples, as shown in FIG. 10, in a direction perpendicular to the array substrate, the array substrate may include a base substrate 100, and a first conductive layer 111, a first insulation layer 101, a second conductive layer 112, a semiconductor layer 110, a second insulation layer 102, a flat layer 105, a third conductive layer 113, a third insulation layer 103, and a fourth conductive layer 114 that are sequentially disposed on the base substrate 100. The first insulation layer 101, the second insulation layer 102 and the third insulation layer 103 may be inorganic insulation layers, and the flat layer 105 may be an organic film.

A manufacturing process for the array substrate in this example will be described below by way of example, with reference to FIGS. 10 to 11C. The manufacturing process for the array substrate in this example may include the following acts.

(3-1) A base substrate is provided.

(3-2) A first conductive layer is formed. In some examples, a first conductive thin film is deposited on the base substrate, and the first conductive thin film is patterned through a patterning process to form a first conductive layer disposed on the base substrate. In some examples, as shown in FIG. 11C, the first conductive layer in the display region may include a data line DL. The data line DL may be of a strip structure extending along a second direction Y. A part of the data line DL may serve as a first electrode 231 of the thin film transistor.

(3-3) A first insulation layer is formed. In some examples, a first insulation thin film is deposited on the base substrate on which the aforementioned structure is formed, and the first insulation thin film is patterned through a patterning process to form a first insulation layer. In some examples, as shown in FIG. 11C, the first insulation layer may be provided with a first via K1 in the display region, and a first insulation layer within the first via K1 may be removed to expose a portion of a surface of the data line DL, and the exposed portion of the data line DL may serve as the first electrode 231 of the thin film transistor to be electrically connected to an active layer 230.

(3-4) A second conductive layer is formed. In some examples, a second conductive thin film is deposited on the base substrate on which the aforementioned structures are formed, and the second conductive thin film is patterned through a patterning process to form a second conductive layer. In some examples, as shown in FIG. 11C, a second conductive layer in the display region may include a pixel electrode 21. An orthographic projection of the pixel electrode 21 on the base substrate may be overlapped with an orthographic projection of the data line DL on the base substrate. A portion where the orthographic projection of the pixel electrode 21 on the base substrate is overlapped with the orthographic projection of the data line DL on the base substrate may serve as a second electrode 232 of the thin film transistor, to be directly lapped with the active layer 230. However, the embodiment is not limited thereto. In some other examples, the pixel electrode 21 may be located within an opening region OP, and the active layer of the thin film transistor may extend into the opening region OP to achieve lapping with the pixel electrode 21.

In some other examples, after forming the first conductive layer, the first insulation thin film and the second conductive thin film can be sequentially deposited on the base substrate, and then the second conductive thin film is patterned to form the second conductive layer, and then the first insulation thin film is patterned to form the first insulation layer.

(3-5) A semiconductor layer is formed. In some examples, a semiconductor thin film is deposited on the base substrate on which the aforementioned structures are formed, and the semiconductor thin film is patterned through a patterning process to form a semiconductor layer. In some examples, as shown in FIGS. 10 and 11C, the semiconductor layer in the display region may include the active layer 230 of the thin film transistor 21. An orthographic projection of the active layer 230 on the base substrate may be at least partially overlapped with the orthographic projection of the data line DL on the base substrate. For example, the orthographic projection of the active layer 230 on the base substrate may be within the range of the orthographic projection of the data line DL on the base substrate. The active layer 230 may extend along the second direction Y. The orthographic projection of the active layer 230 on the base substrate may cover an orthographic projection of the first via K1 on the base substrate, and the active layer 230 may be electrically connected to the first electrode 231 of the thin film transistor through the first via K1, and directly lapped with the second electrode 232 of the thin film transistor. In this example, by disposing the second electrode 232 of the thin film transistor to be directly lapped with the active layer 230, the opening process can be reduced, and manufacturing acts can be simplified. By providing the active layer 230 on the data line DL, a space of the opening region occupied by the thin film transistor can be reduced, which is beneficial to improving the aperture ratio of the display region.

(3-6) A second insulation layer is formed. In some examples, a second insulation thin film is deposited on the base substrate on which the aforementioned structures are formed, so as to form a second insulation layer. In some examples, the second insulation layer may be made of any one or more of silicon oxide (SiOx, x >0), silicon nitride (SiNy, y >0), silicon oxynitride (SiOxNy, x, y >0), alumina (Al₂O₃), and hafnium dioxide (HfO₂), and it may be mono-layered, multi-layered, or a composite layer, such as in a laminated structure of a SiOx layer and a SiNx layer. However, the embodiment is not limited thereto.

(3-7) A flat layer and a third conductive layer are formed. In some examples, a flat thin film is coated on the base substrate on which the aforementioned structures are formed. The flat thin film may have a strong flattening ability, and is capable of withstanding relative high temperatures. For example, a material of the flat thin film may be an organic material with high temperature resistance and low gas emission. For example, the material may include synthetic resin, organosiloxane and the like. A thickness of the flat thin film may range from 0.3 microns to 1.0 microns.

In some examples, a third conductive thin film is deposited on the base substrate on which the aforementioned structures are formed, and the third conductive thin film is patterned through a patterning process to form a third conductive layer. As shown in FIGS. 10 and 11A, the third conductive layer may include a gate line GL located in the display region, and a first trace line 31 located in a peripheral region. An orthographic projection of the gate line GL on the base substrate may be overlapped with the orthographic projection of the active layer on the base substrate. A part of the gate line GL may serve as a gate electrode 233 of the thin film transistor. The orthographic projection of the gate line GL on the base substrate may cover the orthographic projection of the first via K1 on the base substrate.

In some examples, after forming the third conductive layer, the flat thin film may be etched using the third conductive layer as a hard mask, thereby forming a flat layer 105. As shown in FIGS. 11A and 11B, the flat thin film which is not shielded by the third conductive layer may be all etched away, and the flat thin film shielded by the third conductive layer may remain to form the flat layer 105. In this example, the active layer, the second insulation layer, and the flat layer may be sequentially provided within the first via K1, so that the entire surface of a side of the gate line GL away from the base substrate (i.e., a second surface of the gate electrode) may be substantially a flat surface. At a micro-scale, a flatness of the first surface is different from a flatness of the second surface due to an influence of the etching process. In this example, the third conductive layer is used as the hard mask to etch the flat thin film, which can ensure the conducting effect of the semiconductor layer.

In some examples, a switching characteristic of a channel region of the thin film transistor may be controlled by controlling a distance (i.e. the aforementioned second length d1) between an edge of the first via K1 and an edge of an adjacent gate line GL in an extending direction of the active layer 230. A size of the first length may be adjusted according to a characteristic control capability and a graphical process capability. For example, the second length d1 may be greater than 0 and less than or equal to 2 microns to ensure the switching characteristic of the channel region of the thin film transistor.

In some examples, after forming the third conductive layer and the flat layer 105, conducting treatment can be performed on a semiconductor layer not covered by the third conductive layer. For example, a conducting method may include plasma treatment, doping treatment, or the like, in use of a gas such as hydrogen (H), ammonia (NH₃), helium (He), argon (Ar), or the like. This embodiment is not limited thereto.

(3-8) A third insulation layer is formed. In some examples, a third insulation thin film is deposited on the base substrate on which the aforementioned structures are formed, and the third insulation thin film is patterned through a patterning process to form a third insulation layer. As shown in FIG. 10, the third insulation layer may be provided with a via in the bezel region, for example, a second via K2 may be included. A third insulation layer in the display region does not need to be provided with a via, which is beneficial to improving the aperture ratio of the display region.

(3-9) A fourth conductive layer is formed. In some examples, a fourth conductive thin film is deposited on the base substrate on which the aforementioned structures are formed, and the fourth conductive thin film is patterned through a patterning process to form a fourth conductive layer. As shown in FIG. 10, the fourth conductive layer 114 may include a common electrode 22 located at least in the display region AA, and a second trace 32 located in the bezel region BB. The second trace 32 may be electrically connected to the first trace 31 through a second via K2 opened in the third insulation layer 103. In this example, the signal input and transfer are achieved by providing the vias in the bezel region, and the opening region in the display region does not need to be provided with a via, which is beneficial to improving the aperture ratio of the display region.

According to the array substrate in this example, by providing the flat layer with strong filling ability, the surface (i.e., a second plane) of a side of the gate electrode of the thin film transistor close to the base substrate is substantially a flat surface, thereby increasing a distance between the gate electrode and the first electrode of the thin film transistor to improve a voltage rating of the thin film transistor.

Remaining structures of and manufacturing descriptions for the array substrate in this example may be referred to the description of the aforementioned embodiments, which is not repeated here.

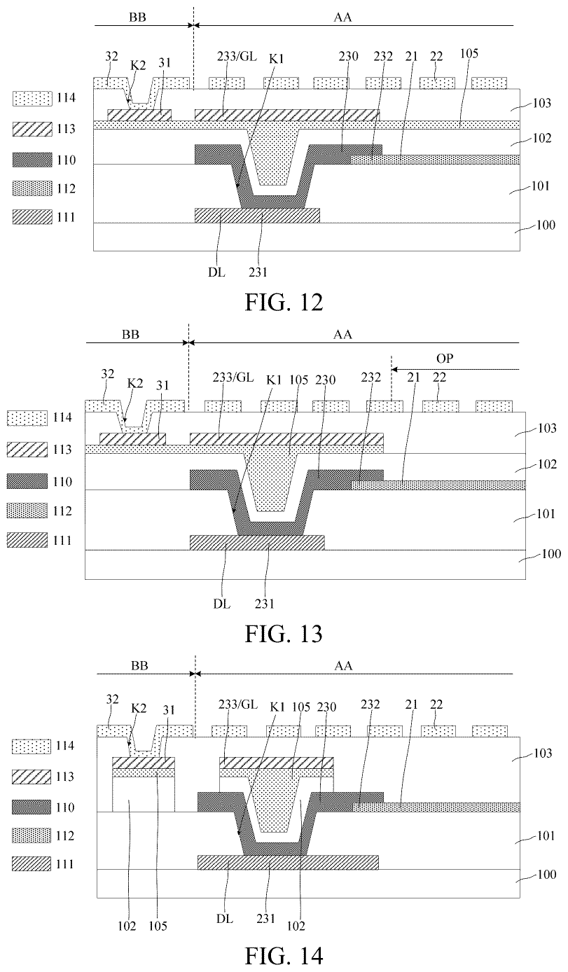

FIG. 12 illustrates schematically another cross-sectional view of a part of an array substrate according to at least one embodiment of the present disclosure. The schematic plan view of the display region of the array substrate in this example can be shown with reference to FIG. 7. In some examples, as shown in FIG. 12, in a direction perpendicular to the array substrate, the array substrate may include a base substrate 100, and a first conductive layer 111, a first insulation layer 101, a second conductive layer 112, a semiconductor layer 110, a second insulation layer 102, a flat layer 105, a third conductive layer 113, a third insulation layer 103, and a fourth conductive layer 114 that are sequentially disposed on the base substrate 100. The first insulation layer 101, the second insulation layer 102 and the third insulation layer 103 may be inorganic insulation layers, and the flat layer 105 may be an organic film.

In this example, the semiconductor layer 110 may include an active layer 230 of a thin film transistor. As shown in FIG. 7, an orthographic projection of a gate line GL on the base substrate may cover an orthographic projection of the active layer 230 on the base substrate. The active layer 230 of the thin film transistor is located below the gate line GL, so that conducting processing may not need to be performed on the semiconductor layer, switching of the transistor may be implemented through a scanning signal transmitted by the gate line GL, and this may simplify the manufacturing process. Since conducting treatment does not need to be performed in this example, a flat layer can be directly formed without patterning after a flat thin film is coated. The flat thin film in this example may be not etched, and this does not affect the semiconductor layer.

According to the array substrate in this example, by providing the flat layer with strong filling ability, a surface (i.e., a second plane) of a side of a gate electrode of the thin film transistor close to the base substrate is substantially a flat surface, thereby increasing a distance between the gate electrode and a first electrode of the thin film transistor to improve a voltage rating of the thin film transistor.

Remaining structures of and manufacturing descriptions for the array substrate in this example may be referred to the description of the aforementioned embodiments, which is not repeated here.

FIG. 13 illustrates schematically another cross-sectional view of a part of an array substrate according to at least one embodiment of the present disclosure. The schematic plan view of the display region of the array substrate in this example can be shown with reference to FIG. 7. In some examples, as shown in FIG. 13, in a direction perpendicular to the array substrate, the array substrate may include a base substrate 100, and a first conductive layer 111, a first insulation layer 101, a second conductive layer 112, a semiconductor layer 110, a second insulation layer 102, a flat layer 105, a third conductive layer 113, a third insulation layer 103, and a fourth conductive layer 114 that are sequentially disposed on the base substrate 100. The first insulation layer 101, the second insulation layer 102 and the third insulation layer 103 may be inorganic insulation layers, and the flat layer 105 may be an organic film.

In this example, as shown in FIG. 13, a flat layer 105 within an opening region OP of a display region AA may be removed, such that an electric field effect of the opening region OP can be ensured.

According to the array substrate in this example, by providing the flat layer with strong filling ability, a surface (i.e., a second plane) of a side of a gate electrode of the thin film transistor close to the base substrate is substantially a flat surface, thereby increasing a distance between the gate electrode and a first electrode of the thin film transistor to improve a voltage rating of the thin film transistor. Moreover, by removing the flat layer within the opening region, it is beneficial to ensure the electric field effect of the opening region.

Remaining structures of and manufacturing descriptions for the array substrate in this example may be referred to the description of the aforementioned embodiments, which is not repeated here.

FIG. 14 illustrates schematically another cross-sectional view of a part of an array substrate according to at least one embodiment of the present disclosure. The schematic plan view of the display region of the array substrate in this example can be shown with reference to FIG. 11A. In some examples, as shown in FIG. 14, in a direction perpendicular to the array substrate, the array substrate may include a base substrate 100, and a first conductive layer 111, a first insulation layer 101, a second conductive layer 112, a semiconductor layer 110, a second insulation layer 102, a flat layer 105, a third conductive layer 113, a third insulation layer 103, and a fourth conductive layer 114 that are sequentially disposed on the base substrate 100. The first insulation layer 101, the second insulation layer 102 and the third insulation layer 103 may be inorganic insulation layers, and the flat layer 105 may be an organic film.

In this example, the semiconductor layer 110 may include an active layer 230 of a thin film transistor. As shown in FIG. 11A, an orthographic projection of a data line DL on the base substrate may cover an orthographic projection of the active layer 230 on the base substrate. The active layer 230 of the thin film transistor is located below the data line DL, such that a space of an opening region occupied by the thin film transistor can be reduced, and this is beneficial to improving an aperture ratio of the display region.

In this example, as shown in FIG. 14, after the semiconductor layer is formed, a second insulation thin film may be deposited and a flat thin film may be coated, and then the third conductive layer may be formed. After the third conductive layer is formed, the flat thin film and the second insulation thin film may be etched by using the third conductive layer as a hard mask, so as to form the flat layer 105 and the second insulation layer 102. An orthographic projection of the second insulation layer 102 on the base substrate may coincide with an orthographic projection of the flat layer 105 on the base substrate. In this example, a conducting effect of the semiconductor layer can be ensured by etching away a second insulation thin film and a flat film that are not covered by the third conductive layer.

In this example, an active layer 230, a second insulation layer 102 and a flat layer 105 may be disposed in sequence within the first via K1 opened in the first insulation layer 101, so that a surface (i.e., a second plane) of a side of a gate electrode of the thin film transistor close to the base substrate is substantially a flat surface, thereby increasing a distance between the gate electrode and a first electrode of the thin film transistor to improve a voltage rating of the thin film transistor.

Remaining structures of and manufacturing descriptions for the array substrate in this example may be referred to the description of the aforementioned embodiments, which is not repeated here.

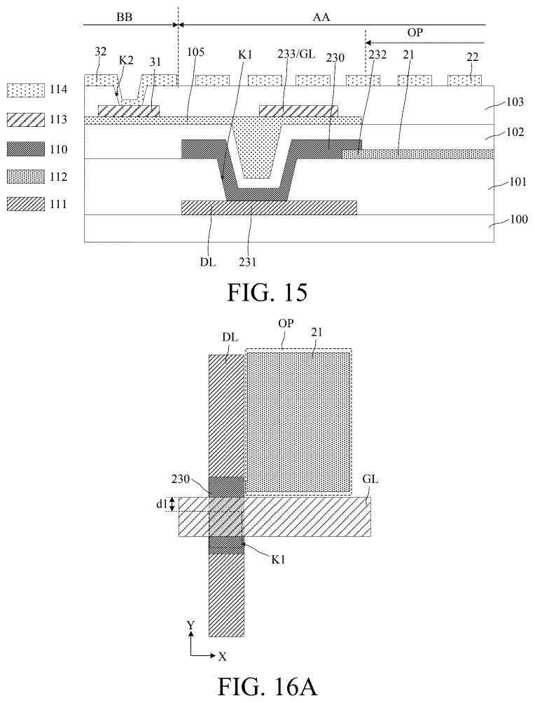

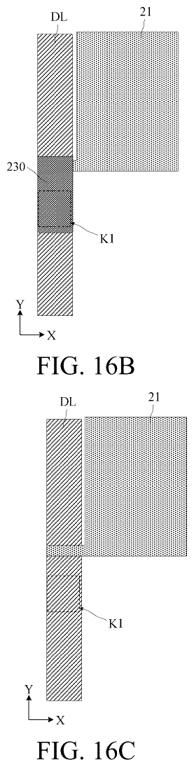

FIG. 15 illustrates schematically another cross-sectional view of a part of an array substrate according to at least one embodiment of the present disclosure. FIG. 16A is another plan view of a part of a display region of an array substrate according to at least one embodiment of the present disclosure. FIG. 16B is a plan view of the array substrate after a semiconductor layer is formed in FIG. 16A. FIG. 16C is a plan view of the array substrate after a second conductive layer is formed in FIG. 16A.

In some examples, as shown in FIG. 15, in a direction perpendicular to the array substrate, the array substrate may include a base substrate 100, and a first conductive layer 111, a first insulation layer 101, a second conductive layer 112, a semiconductor layer 110, a second insulation layer 102, a flat layer 105, a third conductive layer 113, a third insulation layer 103, and a fourth conductive layer 114 that are sequentially disposed on the base substrate 100. The first insulation layer 101, the second insulation layer 102 and the third insulation layer 103 may be inorganic insulation layers, and the flat layer 105 may be an organic film.

In some examples, as shown in FIGS. 15 to 16, the first conductive layer 111 may include a data line DL. The data line DL may be of a strip structure extending along a second direction Y. A part of the data line DL may serve as a first electrode 231 of the thin film transistor. The first insulation layer 101 may be provided with a first via K1 in the display region AA, and a first insulation layer 101 within the first via K1 may be removed to expose a portion of a surface of the data line DL, and the exposed portion of the data line DL may serve as the first electrode 231 of the thin film transistor to be electrically connected to an active layer 230. The second conductive layer 112 may include a pixel electrode 21. An orthographic projection of the pixel electrode 21 on the base substrate may be overlapped with an orthographic projection of the data line DL on the base substrate. A portion where the orthographic projection of the pixel electrode 21 on the base substrate is overlapped with the orthographic projection of the data line DL on the base substrate may serve as a second electrode 232 of the thin film transistor to be directly lapped with the active layer 230. The semiconductor layer 110 may include the active layer 230 of the thin film transistor. An orthographic projection of the active layer 230 on the base substrate may be within a range of the orthographic projection of the data line DL on the base substrate. The active layer 230 may extend along the second direction Y. The orthographic projection of the active layer 230 on the base substrate may cover an orthographic projection of the first via K1 on the base substrate, and the active layer 230 may be electrically connected to the first electrode 231 of the thin film transistor through the first via K1, and directly lapped with the second electrode 232 of the thin film transistor.

In some examples, as shown in FIG. 15, the flat layer 105 may be not overlapped with an opening region OP. In other words, a flat layer 105 within the opening region OP may be removed to ensure an electric field effect of the opening region OP. The flat layer 105 can flatten the first via K1 in the first insulation layer, so that a surface of a side of the gate line GL close to the base substrate may be substantially flat, thereby increasing a distance between the gate electrode and the first electrode of the thin film transistor to improve a voltage rating of the thin film transistor. In some examples, a flat layer 105 in a non-opening region of the display region may remain completely, or the flat layer 105 in the non-opening region of the display region may remain partially, leaving only a portion which covers the first via K1. For example, a flat thin film may be etched by using the third conductive layer as a hard mask, so as to form the flat layer.

In some examples, as shown in FIGS. 15 and 16A, the third conductive layer 113 may include a gate line GL located in the display region, and a first trace line 31 located in a peripheral region. An orthographic projection of the gate line GL on the base substrate may be overlapped with the orthographic projection of the active layer on the base substrate. A part of the gate line GL may serve as a gate electrode 233 of the thin film transistor. The orthographic projection of the gate line GL on the base substrate may be partially overlapped with the orthographic projection of the first via K1 on the base substrate. For example, the gate line GL may be located on a side of the first via K1 close to the pixel electrode 21. For example, an area of the first via K1 covered by the gate line GL may account for half of a total area of the first via K1. In other words, the gate line GL may cover half of the area of the first via K1. In this example, by reducing an overlapping area between the gate line and the first electrode of the thin film transistor, capacitance between the gate electrode and the first electrode of the thin film transistor can be reduced, thereby reducing power consumption. Moreover, a space occupied by the gate line in the opening region can be reduced, so as to improve an aperture ratio of the display region.

In some examples, as shown in FIG. 16A, the orthographic projection of the gate line GL on the base substrate may be not overlapped with the orthographic projection of the pixel electrode 21 on the base substrate, and a switching characteristic of a channel region of the thin film transistor may be controlled by controlling a distance (for example, corresponding to a second length d1) between an edge of the first via K1 and an edge of an adjacent gate line GL in an extending direction of the active layer 230. In some other examples, when the orthographic projection of the gate line on the base substrate is overlapped with the orthographic projection of the pixel electrode on the base substrate, the switching characteristic of the channel region of the thin film transistor may be controlled by controlling a distance (for example, corresponding to a fourth length d2) between an edge of the first via K1 and an edge of an adjacent pixel electrode in an extending direction of the active layer.

In some examples, as shown in FIG. 15, the fourth conductive layer 114 may include a common electrode 22 located at least in the display region AA, and a second trace 32 located in a bezel region BB. An orthographic projection of the common electrode 22 on the base substrate is overlapped with the orthographic projection of the pixel electrode 21 on the base substrate.

Remaining structures of and manufacturing descriptions for the array substrate in this example may be referred to the description of the aforementioned embodiments, which is not repeated here.

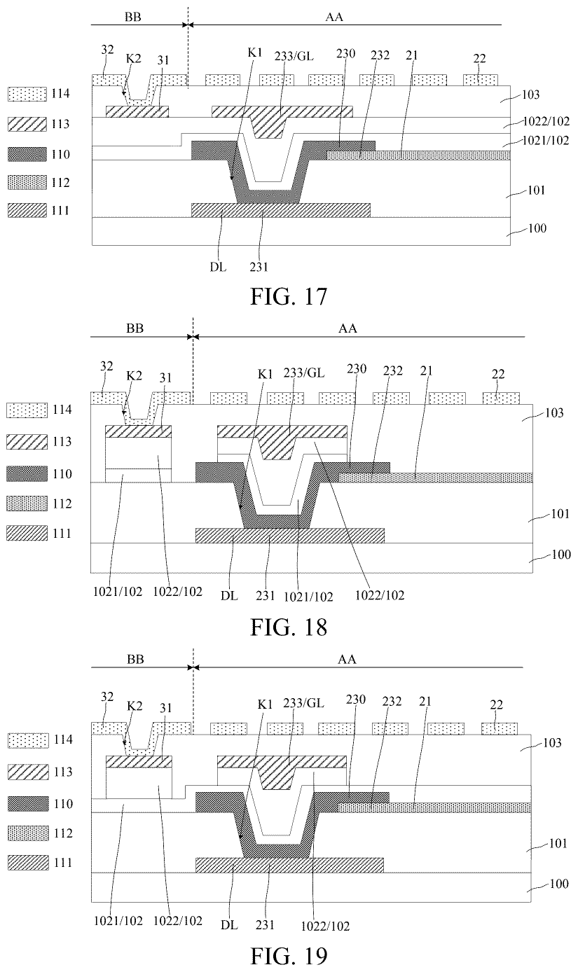

FIG. 17 illustrates schematically another cross-sectional view of a part of an array substrate according to at least one embodiment of the present disclosure. The schematic plan view of the display region of the array substrate in this example can be shown with reference to FIG. 3. In some examples, as shown in FIG. 17, in a direction perpendicular to the array substrate, the array substrate may include a base substrate 100, and a first conductive layer 111, a first insulation layer 101, a second conductive layer 112, a semiconductor layer 110, a second insulation layer 102, a third conductive layer 113, a third insulation layer 103, and a fourth conductive layer 114 that are sequentially disposed on the base substrate 100. The first insulation layer 101, the second insulation layer 102, and the third insulation layer 103 may be inorganic insulation layers. The second insulation layer 102 may include a first sub-insulation layer 1021 and a second sub-insulation layer 1022 which is located on a side of the first sub-insulation layer 1021 away from the base substrate 100.

In this example, the semiconductor layer 110 may include an active layer 230 of a thin film transistor. As shown in FIG. 3, an orthographic projection of a data line DL on the base substrate may cover an orthographic projection of the active layer 230 on the base substrate. The active layer 230 of the thin film transistor is located below the data line DL, which can simplify a manufacturing process, reduce a space occupied by the thin film transistor, and help the improvement of an aperture ratio of the display region.

In some examples, as shown in FIG. 17, both the first sub-insulation layer 1021 and the second sub-insulation layer 1022 may be inorganic insulation layers, for example, may include one or more inorganic films stacked. The first sub-insulation layer 1021 and the second sub-insulation layer 1022 may be not etched in this example.

In some examples, a dielectric constant (K value) of at least one of a plurality of inorganic films included in the second insulation layer 102 may be greater than or equal to 7, and a thickness of each inorganic film may be greater than or equal to 50 nanometers. For example, a K value of one of the plurality of inorganic films may be greater than or equal to 10. For example, a thickness of at least one inorganic film may be greater than or equal to 50 nanometers, and less than or equal to 300 nanometers. In this example, by setting a plurality of stacked inorganic films as the second insulation layer and limiting the K values and the thicknesses of the inorganic films, characteristics of turning-on and turning-off of the thin film transistor can be ensured while an insulating effect is ensured.

In some examples, the first sub-insulation layer 1021 may be made of any one or more of silicon oxide (SiOx, x >0), silicon nitride (SiNy, y >0), silicon oxynitride (SiOxNy, x, y >0), alumina (Al₂O₃), and hafnium dioxide (HfO₂), for example, it may be mono-layered, or multi-layered. At least one inorganic film included in the first sub-insulation layer 1021 may be an oxidized insulation layer, which, for example, may be deposited by means of Atomic Layer Deposition (ALD), herein the insulation layer formed by means of ALD may be referred to as an ALD oxidized insulation layer. In this example, coverage of the second insulation layer to the semiconductor layer can be improved by providing the first sub-insulation layer.

In some examples, the second sub-insulation layer 1022 may be made of any one or more of a silicon nitride (SiNx, x >0) and a HKL (High K Layer) material, and may be mono-layered, multi-layered, or a composite layer. The second sub-insulation layer 1022 may include an inorganic film of at least one of a silicon nitride film and an HKL film. A K value of the HKL film may be greater than or equal to 7, for example, may be greater than or equal to 10. For example, the second sub-insulation layer 1022 may be a single layer of SiNx, or may be of a laminated structure of a SiNx layer and an HKL layer. In this example, by providing the second sub-insulation layer 1022 including SiNx, it is possible to improve a via coverage and reduce a risk of crack in the second insulation layer, and it is possible to avoid short circuit or burning of the third conductive layer and the semiconductor layer or the first conductive layer through a crack region. By providing the second sub-insulation layer 1022 including HKL, it is possible to improve the resistance to electrical breakdown by increasing a dielectric capability of the second insulation layer, reducing a leakage current of the thin film transistor, and increasing a breakdown voltage between the gate electrode and the first electrode of the thin film transistor. In some examples, the HKL material may include at least one of the following: hafnium dioxide (HfO₂), zirconium dioxide (ZrO₂), hafnium diselenide (HfSe₂), and zirconium diselenide (ZrSe₂).

In some examples, a thickness of the second insulation layer 102 may be about 2000 angstroms and 4000 angstroms. For example, the first sub-insulation layer 1021 may include a SiOx film, and a thickness of the SiOx film may be about 1000 angstroms to 3000 angstroms. The second sub-insulation layer 1022 may include a SiNx film, and a thickness of the SiNx film may be about 1000 angstroms to 3000 angstroms. As another example, the first sub-insulation layer 1021 may include an ALD oxide insulation layer and a SiOx film which are laminated, herein the ALD oxide insulation layer is located on a side of the SiOx film close to the base substrate, and a thickness of the ALD oxide insulation layer may be about 500 angstroms to 1000 angstroms. A thickness of the SiOx film may be about 1000 angstroms to 2000 angstroms. The second sub-insulation layer 1022 may include a SiNx film, and a thickness of the SiNx film may be about 1000 angstroms to 3000 angstroms. As another example, the first sub-insulation layer 1021 may include a SiOx film and may have a thickness of about 1000 angstroms to 2000 angstroms. The second sub-insulation layer 1022 may include an HKL film and a SiNx film which are stacked, the HKL film is located on the side of the SiNx film adjacent to the base substrate, and a SiNx film has a thickness of about 1000 to 2000 angstroms, and a SiNx film has a thickness of about 1000 to 2000 angstroms. As another example, the first sub-insulation layer 1021 may include an ALD oxide insulation layer and a SiOx film which are stacked, the ALD oxide insulation layer is located on a side of the SiOx film close to the base substrate. A thickness of the ALD oxide insulation layer may be about 500 angstroms to 1000 angstroms. A thickness of the SiOx film may be about 1000 angstroms to 2000 angstroms. The second sub-insulation layer 1022 may include an HKL film, and a thickness of the HKL film may be about 1000 angstroms to 2000 angstroms. As another example, the first sub-insulation layer 1021 may include an ALD oxide insulation layer, and a thickness of the ALD oxide insulation layer may be about 500 angstroms to 1000 angstroms. The second sub-insulation layer 1022 may include an HKL film, and a thickness of the HKL film may be about 1000 angstroms to 2000 angstroms. As another example, the first sub-insulation layer 1021 may include a SiOx film, and a thickness of the SiOx film may be about 1000 angstroms to 2000 angstroms. The second sub-insulation layer 1022 may include an HKL film, and a thickness of the HKL film may be about 1000 angstroms to 2000 angstroms.

In this example, by setting the second insulation layer including the SiNx film, the via coverage can be improved, electrostatic discharge and short circuit problems caused by cracks can be avoided, and the dielectric performance of the second insulation layer can be improved, and the resistance to breakdown can be improved. By setting the second insulation layer including the ALD oxide insulation layer, a gap or water vapor impurities at an interface of a front channel can be avoided, and a characteristic of the front channel can be ensured. By setting the second insulation layer including the HKL film, the leakage current of the thin film transistor can be reduced, and the resistance to electrical breakdown can be improved.

Remaining structures of and manufacturing acts for the array substrate in this example may be referred to the description of the aforementioned embodiments, which is not repeated here.

FIG. 18 illustrates schematically another cross-sectional view of a part of an array substrate according to at least one embodiment of the present disclosure. The schematic plan view of the display region of the array substrate in this example can be shown with reference to FIG. 3. In some examples, as shown in FIG. 17, in a direction perpendicular to the array substrate, the array substrate may include a base substrate 100, and a first conductive layer 111, a first insulation layer 101, a second conductive layer 112, a semiconductor layer 110, a second insulation layer 102, a third conductive layer 113, a third insulation layer 103, and a fourth conductive layer 114 that are sequentially disposed on the base substrate 100. The second insulation layer 102 may include a first sub-insulation layer 1021 and a second sub-insulation layer 1022 which is located on a side of the first sub-insulation layer 1021 away from the base substrate 100.

In some examples, since a thickness of the second insulation layer 102 is greater than 2000 angstroms, it is possible to affect a conducting effect, resulting in a poor conducting effect. In this example, after the third conductive layer is formed, the second insulation layer 102 may be etched using the third conductive layer as a hard mask. A first sub-insulation layer 1021 and a second sub-insulation layer 1022 covered by the third conductive layer may be kept, and both a first sub-insulation layer 1021 and a second sub-insulation layer 1022 which are not covered by the third conductive layer may be etched away. In this example, orthographic projections of the first sub-insulation layer 1021 and the second sub-insulation layer 1022 on the base substrate may cover an orthographic projection of the first via K1 on the base substrate to ensure coverage on the via. In this example, by etching both the first sub-insulation layer and the second sub-insulation layer, a conducting effect of the semiconductor layer can be ensured.

Remaining structures of and manufacturing descriptions for the array substrate in this example may be referred to the description of the embodiment shown in FIG. 17, which is not repeated here.

FIG. 19 illustrates schematically another cross-sectional view of a part of an array substrate according to at least one embodiment of the present disclosure. In some examples, as shown in FIG. 19, a part of a second insulation layer 102 of this example may be etched. For example, a second sub-insulation layer 1022 may be etched. For example, after a third conductive layer is formed, the second sub-insulation layer 1022 may be etched using the third conductive layer as a hard mask, while a first sub-insulation layer 1021 remains without etching the first sub-insulation layer 1021. In this example, by etching the part of the second insulation layer, an influence of excessive thickness of the second insulation layer on the conducting effect can be avoided, a conducting effect of a semiconductor layer can be ensured. In some other examples, when at least one of the first sub-insulation layer and the second sub-insulation layer is in a multiple-film laminated structure, at least one of the films may be etched to avoid an influence of excessive thickness of the second insulation layer on the conducting effect.

Remaining structures of and manufacturing descriptions for the array substrate in this example may be referred to the description of the embodiment shown in FIGS. 17 and 18, which is not repeated here.

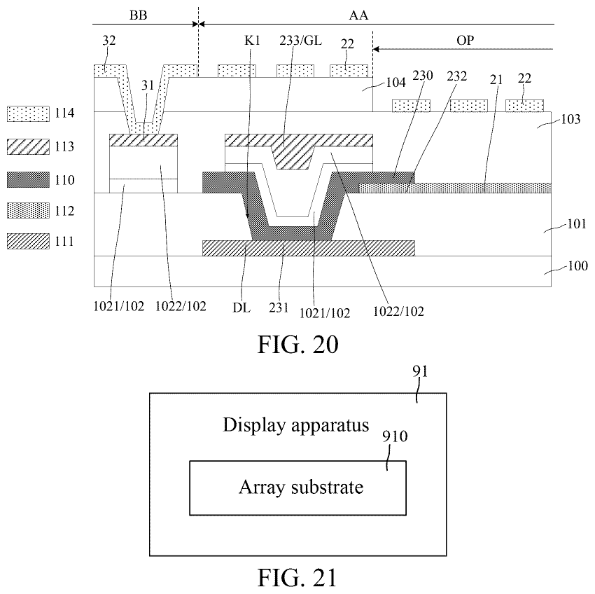

FIG. 20 illustrates schematically another cross-sectional view of a part of an array substrate according to at least one embodiment of the present disclosure. In some examples, as shown in FIG. 20, in a direction perpendicular to the array substrate, the array substrate may include a base substrate 100, and a first conductive layer 111, a first insulation layer 101, a second conductive layer 112, a semiconductor layer 110, a second insulation layer 102, a third conductive layer 113, a third insulation layer 103, a fourth insulation layer 104, and a fourth conductive layer 114 that are sequentially disposed on the base substrate 100. The first insulation layer 101, the second insulation layer 102 and the third insulation layer 103 may be inorganic insulation layers, and the fourth insulation layer 104 may be an organic insulation layer. The second insulation layer 102 may include a first sub-insulation layer 1021 and a second sub-insulation layer 1022 which is located on a side of the first sub-insulation layer 1021 away from the base substrate 100.

In some examples, as shown in FIG. 20, an orthographic projection of the fourth insulation layer 104 on the base substrate 100 may be not overlapped with an orthographic projection of an opening region OP of a display region AA. In other words, a fourth insulation layer 104 within the opening region OP of the display region AA may be removed. In some examples, the fourth insulation layer 104 may be made of an organic material such as polyimide, acrylic, or polyethylene terephthalate. However, the embodiment is not limited thereto.

According to the array substrate in this example, by providing the fourth insulation layer in the non-opening region of the display region, crosstalk caused by a signal transmitted in the gate line to the common electrode can be reduced, and parasitic capacitance between the gate line and the common electrode can be reduced. By removing the fourth insulation layer in the opening region of the display region, a liquid crystal deflection electric field can be ensured, and a liquid crystal electric field effect can be improved.

Remaining structures of and manufacturing descriptions for the array substrate in this example may be referred to the description of the embodiment shown in FIGS. 17 to 19, which is not repeated here.

In other examples, solutions of the abovementioned embodiments may be combined with each other. For example, the second insulation layer in the embodiments shown in FIGS. 2 to 16C may be made of the materials and may be in the structures in the embodiments shown in FIGS. 17 to 19.

A manufacturing method for an array substrate is also provided in an embodiment. The method includes: forming a first conductive layer on the base substrate, herein the first conductive layer includes a first electrode of at least one thin film transistor; forming a first insulation layer on the first conductive layer, herein the first insulation layer is provided with a first via to expose at least part of a surface of the first electrode; forming a second conductive layer and a semiconductor layer on the first insulation layer, herein the semiconductor layer includes an active layer of the thin film transistor, the active layer is electrically connected to the first electrode through the first via, an orthographic projection of the active layer on the base substrate covers an orthographic projection of the first via on the base substrate, and the second conductive layer at least includes a second electrode of the thin film transistor; forming a second insulation layer; forming a third conductive layer on the second insulation layer, herein the third conductive layer at least includes a gate electrode of the thin film transistor, a surface of a side of the gate electrode close to the base substrate is a first surface, a surface of a side of the gate electrode away from the base substrate is a second surface, and a flatness of the first surface is different from a flatness of the second surface.

In some exemplary implementations, the first conductive layer may further include at least one data line, a first electrode of at least one thin film transistor and the data line are of an integral structure; the second conductive layer further includes at least one pixel circuit, and a second electrode of at least one thin film transistor and the pixel circuit are of an integral structure; the third conductive layer further includes at least one gate line, and a gate electrode of at least one thin film transistor and the gate line are of an integral structure.

In some exemplary implementations, the manufacturing method in this example may further include forming a flat layer after the second insulation layer is formed, herein an orthographic projection of the flat layer on the base substrate may cover the orthographic projection of the first via on the base substrate. Description in this example may refer to the foregoing description of the embodiments shown in FIGS. 10 to 15, which is not repeated here. In this example, an ability of the flat layer for filling the first via can ensure a distance between the gate electrode and the first electrode of the thin film transistor, so as to improve a voltage rating of the thin film transistor.

In some exemplary implementations, forming the flat layer may include coating a flat thin film on the base substrate after the second insulation layer is formed, and patterning the flat thin film to form the flat layer. The description of this example may refer to the foregoing description in the embodiment shown in FIGS. 13 and 15, which is not repeated here. In some other examples, forming the flat layer may include: coating a flat thin film on the base substrate after the second insulation layer is formed, and etching the flat film by using the third conductive layer as a hard mask after the third conductive layer is formed on the flat film, so as to form the flat layer. The description of this example may refer to description in the embodiment shown in FIGS. 10 and 14, which is not repeated here.

In some exemplary implementations, the base substrate may include a display region, and at least one data line disposed in the display region may intersect with at least one gate line disposed in the display region to form a plurality of sub-pixel regions, the sub-pixel regions include an opening region for display and a non-opening region located on at least one side of the opening region. The flat layer may be not overlapped with the opening region. Description in this example may refer to the description in the embodiment shown in FIG. 15, which is not repeated here. In this example, an electric field effect of the opening region can be ensured by removing a flat layer in the opening region.

In some exemplary implementations, forming the second insulation layer may include sequentially depositing a plurality of inorganic films on the base substrate after the semiconductor layer is formed, so as to form the second insulation layer. The plurality of inorganic films satisfy at least one of the following: a dielectric constant of at least one inorganic film is greater than or equal to 7, and a thickness of each inorganic film is greater than or equal to 50 nanometers. Description in this example may refer to the description in the embodiment shown in FIG. 17, which is not repeated here. In other examples, forming the second insulation layer may include sequentially depositing a plurality of inorganic films on the base substrate after the semiconductor layer is formed, and etching at least one of the plurality of inorganic films by using the third conductive layer as a hard mask after the third conductive layer is formed, so as to form the second insulation layer. The plurality of inorganic films may include at least two of the following: an oxide insulation layer, a silicon nitride film, and an HKL film. Description in this example may refer to the description in the embodiment shown in FIGS. 18 to 20. In some examples, the second insulation layer may include an oxide insulation layer and a silicon nitride film sequentially disposed along a direction away from the base substrate. Or, the second insulation layer may include an oxide insulation layer, an HKL film, and a silicon nitride film sequentially disposed in a direction away from the base substrate. Or, the second insulation layer may include an oxide insulation layer and an HKL film sequentially disposed along a direction away from the base substrate.

In some exemplary implementations, the manufacturing method in this example may further include: after forming the third conductive layer, sequentially forming a third insulation layer and a fourth conductive layer, or sequentially forming a third insulation layer, a fourth insulation layer and a fourth conductive layer. The fourth conductive layer may at least include a common electrode. The third insulation layer may be an inorganic insulation layer, and the fourth insulation layer may be an organic insulation layer. In some examples, the fourth insulation layer may be not overlapped with the opening region. Description in this example may refer to the description in the embodiment shown in FIGS. 6 to 20. In this example, a liquid crystal electric field effect can be improved by removing a fourth insulation layer in the opening region.

Remaining description of the manufacturing method for an array substrate in this embodiment may refer to the description in the foregoing embodiments, which is not repeated here.

FIG. 21 is a schematic diagram of a display apparatus according to at least one embodiment of the present disclosure. As shown in FIG. 21, a display apparatus 91 is provided in this embodiment, which may include an array substrate 910 as described above.

In some examples, the display apparatus 91 may include an array substrate 910, an opposed substrate, and a liquid crystal layer disposed between the array substrate and the opposed substrate. A pixel electrode and a common electrode included in the array substrate 910 may be configured to generate an electric field that controls deflection of liquid crystal molecules in the liquid crystal layer. In some examples, the opposed substrate may include an underlying substrate, and a black matrix and a color film disposed on the underlying substrate. However, the embodiment is not limited thereto.

In some examples, the display apparatus 91 may be any product or component having a display function such as a liquid crystal panel, an electronic paper, a mobile phone, a tablet computer, a television, a display, a laptop computer, a digital photo frame, or a navigator. The embodiment is not limited thereto.

The drawings of the present disclosure only involve structures involved in the present disclosure, and other structures may refer to conventional designs. The embodiments of the present disclosure and features in the embodiments may be combined to each other to obtain new embodiments if there is no conflict. Those of ordinary skills in the art should understand that modifications or equivalent replacements may be made to the technical solutions of the present disclosure without departing from the essence and scope of the technical solutions of the present disclosure, and shall all fall within the scope of the claims of the present disclosure.

1. A thin film transistor, comprising: a first electrode, a second electrode, an active layer and a gate electrode, which are disposed on a base substrate; wherein
the active layer is electrically connected with the first electrode and the second electrode, the gate electrode is located on a side of the active layer away from the base substrate, the first electrode is located on a side of the active layer close to the base substrate, a first insulation layer is disposed between the first electrode and the active layer, the first insulation layer is provided with a first via, the active layer is electrically connected to the first electrode through the first via, and an orthographic projection of the active layer on the base substrate covers an orthographic projection of the first via on the base substrate;
a second insulation layer is disposed between the gate electrode and the active layer; an orthographic projection of the gate electrode on the base substrate is overlapped, at least partially, with the orthographic projection of the first via on the base substrate, a surface of a side of the gate electrode close to the base substrate is a first surface, and a surface of a side of the gate electrode away from the base substrate is a second surface, a flatness of the first surface differs from a flatness of the second surface.

2. The thin film transistor of claim 1, wherein the second surface of the gate electrode is a flat surface, and a vertical distance between the first electrode and the base substrate differs from a vertical distance between the second electrode and the base substrate.

3. The thin film transistor of claim 1, wherein the active layer comprises a channel region, and an orthographic projection of the channel region on the base substrate is located within a range of the orthographic projection of the gate electrode on the base substrate;
the channel region comprises a first channel portion and a second channel portion connected to each other, an orthographic projection of the first channel portion on the base substrate is overlapped, at least partially, with an orthographic projection of a sidewall of the first via on the base substrate;
the second channel portion is located on a surface of a side of the first insulation layer away from the base substrate, and is not overlapped with the orthographic projection of the first via on the base substrate.

4. The thin film transistor of claim 3, wherein an included angle between the first channel portion and the second channel portion ranges from 90 degrees to 160 degrees in a plane perpendicular to the base substrate and parallel to an extending direction of the active layer.

5. The thin film transistor of claim 3, wherein a ratio of a length of the second channel portion to a length of the first channel portion is greater than or equal to 1, and a ratio of a thickness of the second channel portion to a thickness of the first channel portion is greater than or equal to 1.

6. The thin film transistor of claim 3, wherein a length of the first channel portion is greater than 0 and less than or equal to 5 microns, and a length of the second channel portion is greater than 0 and less than or equal to 5 microns.

7. The thin film transistor of claim 1, wherein the second electrode is located on the side of the active layer close to the base substrate, and the active layer is directly lapped with the second electrode.

8. The thin film transistor of claim 1, wherein the active layer, the second insulation layer, and the gate electrode are sequentially disposed within the first via.

9. The thin film transistor of claim 1, wherein a flat layer is disposed between the second insulation layer and the gate electrode, an orthographic projection of the flat layer on the base substrate covers at least the orthographic projection of the first via on the base substrate.

10. The thin film transistor of claim 9, wherein the orthographic projection of the flat layer on the base substrate covers the orthographic projection of the gate electrode on the base substrate, and the second surface of the gate electrode is a flat surface.

11. The thin film transistor of claim 1, wherein an orthographic projection of the second insulation layer on the base substrate covers at least orthographic projections of the first via and the gate electrode on the base substrate.

12. The thin film transistor of claim 11, wherein the second insulation layer comprises a plurality of inorganic films which are stacked, the plurality of inorganic films satisfy at least one of the following: at least one inorganic film has a dielectric constant greater than or equal to 7, and a thickness of each inorganic film is greater than or equal to 50 nanometers.

13. An array substrate, comprising: a base substrate, and at least one thin film transistor of claim 1, at least one data line, at least one gate line, and at least one pixel electrode, which are disposed on the base substrate; wherein a gate electrode of the thin film transistor is electrically connected with a gate line, a first electrode of the thin film transistor is electrically connected with a data line, and a second electrode of the thin film transistor is electrically connected with a pixel electrode.

14. The array substrate of claim 13, wherein the first electrode of the thin film transistor and the data line are of an integral structure, the gate electrode of the thin film transistor and the gate line are of an integral structure, and the second electrode of the thin film transistor and the pixel electrode are of an integral structure.

15. The array substrate of claim 13, wherein an orthographic projection of an active layer of the thin film transistor on the base substrate is partially overlapped with an orthographic projection of at least one of the data line and the gate line on the base substrate.

16. The array substrate of claim 13, wherein the base substrate comprises a display region where the at least one data line intersects with the at least one gate line to form a plurality of sub-pixel regions, a sub-pixel region comprises an opening region for display and a non-opening region on at least one side of the opening region, and the pixel electrode is located at least within the opening region; the thin film transistor, the data line and the gate line are located in the non-opening region.

17. The array substrate of claim 16, wherein a second insulation layer is disposed between the gate electrode and the active layer of the thin film transistor, a flat layer is disposed between the second insulation layer and the gate electrode, and the flat layer is not overlapped with the opening region.

18. The array substrate of claim 16, further comprising: a third insulation layer and a common electrode which are located on a side of the gate line away from the base substrate, wherein the common electrode is located at least within the opening region, and an orthographic projection of the common electrode on the base substrate is, at least partially, overlapped with an orthographic projection of the pixel electrode on the base substrate.

19. The array substrate of claim 18, further comprising: a fourth insulation layer located on a side of the third insulation layer away from the base substrate, wherein the fourth insulation layer is not overlapped with the opening region.

20. A manufacturing method for an array substrate, comprising:
forming a first conductive layer on a base substrate, wherein the first conductive layer comprises a first electrode of at least one thin film transistor;
forming a first insulation layer on the first conductive layer, wherein the first insulation layer is provided with a first via to expose at least part of a surface of the first electrode;
forming a second conductive layer and a semiconductor layer on the first insulation layer, wherein the semiconductor layer comprises an active layer of the thin film transistor, the active layer is electrically connected to the first electrode through the first via, an orthographic projection of the active layer on the base substrate covers an orthographic projection of the first via on the base substrate, and the second conductive layer at least comprises a second electrode of the thin film transistor;
forming a second insulation layer; and
forming a third conductive layer on the second insulation layer, wherein the third conductive layer at least comprises a gate electrode of the thin film transistor; a surface of a side of the gate electrode close to the base substrate is a first surface, and a surface of a side of the gate electrode away from the base substrate is a second surface, and a flatness of the first surface differs from a flatness of the second surface.

21-24. (canceled)
